(19) United States
(12) Patent Application Publication
(10) Pub. No.: US 2012/0170242 A1
(43) Pub. Date: Jul. 5, 2012

(54) CIRCUIT BOARD, CONNECTING STRUCTURE OF CIRCUIT BOARDS, AND DISPLAY PANEL ASSEMBLY

(75) Inventors: Kohji Minamino, Osaka-shi (JP); Yoshiaki Honda, Osaka-shi (JP)

(73) Assignee: SHARP KABUSHIKI KAISHA, Osaka-shi (JP)

(21) Appl. No.: 13/376,092

(22) PCT Filed: May 21, 2010
(86) PCT No.: PCT/JP2010/058584

§ 371 Date: Mar. 14, 2012

(30) Foreign Application Priority Data
Jun. 3, 2009 (JP) 13376092

(51) Int. Cl. H05K 1/14; H05K 1/02

(52) U.S. Cl. 361/803; 174/250

(57) ABSTRACT

A circuit board that allows a conductive material such as an anisotropic conductive film to improve its connection strength. A circuit board (1) includes a first area (12) including a predetermined number of electrode terminals (121), and a second area (13) including a predetermined number of structural members (131a) having an island shape, wherein the first area and the second area are aligned in a first direction, wherein at least some of the island-shaped structural members have a size in a direction substantially perpendicular to the first direction that is smaller than a size in the direction substantially perpendicular to the first direction of the second area.

### REFERENCE TO RELATED APPLICATIONS

This application is the national stage under 35 USC 371 of International Application No. PCT/JP2010/058584, filed May 21, 2010 which claims priority from Japanese Patent Application No. 2009-133767, filed Jun. 3, 2009, the entire contents of which are incorporated herein by reference.

### FIELD OF THE INVENTION

The present invention relates to a circuit board, a connecting structure of circuit boards, and a display panel assembly. The present invention more specifically relates to a circuit board that is capable of being connected to another circuit board with the use of a conductive material such as an anisotropic conductive film, a connecting structure of circuit boards that are capable of being connected to each other with the use of a conductive material such as an anisotropic conductive film, and a display panel assembly including the circuit boards. It is to be noted that the “display panel assembly” defines a display panel to which circuit boards are connected.

### BACKGROUND OF THE INVENTION

In general, an active matrix type liquid crystal display panel includes a TFT array substrate and a common substrate (a color filter is usually used as the common substrate). The TFT array substrate and the common substrate are opposed to each other having a given tiny space therebetween, and liquid crystals are filled between the substrates. A display panel assembly includes the liquid crystal display panel and circuit boards that are connected to the liquid crystal display panel.

The TFT array substrate for the active matrix type liquid crystal display panel usually includes an active area and a peripheral area of a panel that surrounds the active area. The active area is referred to also as a “display area” or a “pixel area”.

A given number of pixel electrodes are provided in a given arrangement, and switching elements arranged to drive the pixel electrodes are provided in a given arrangement in the active area. TFTs (Thin Film Transistors) are usually used as the switching elements. Gate lines arranged to send given signals to gate electrodes of the switching elements and source lines arranged to send given signals to source electrodes of the switching elements are also provided in the active area. It is to be noted that the gate lines are referred to also as “scanning lines” or “gate bus lines”, and the source lines are referred to also as “data lines” or “source bus lines”.

Meanwhile, connecting areas to which circuit boards are to be connected are provided in the peripheral area of the panel. The connecting areas include wiring electrode terminals that are electrically connected to corresponding gate lines or source lines.

The circuit boards of the display panel assembly include circuit boards each incorporating driver ICs or driver Sis (hereinafter, referred to as the “gate drivers”) arranged to generate signals sent to the gate electrodes of the switching elements, circuit boards each incorporating driver ICs or driver Sis (hereinafter, referred to as the “source drivers”) arranged to generate signals sent to the source electrodes of the switching elements, a circuit board arranged to send signals from the outside to the circuit boards incorporating the gate drivers (hereinafter, referred to as the “gate-side common circuit board”), and a circuit board arranged to send signals from the outside to the circuit boards incorporating the source drivers (hereinafter, referred to as the “source-side common circuit board”).

Flexible circuit boards produced by a TAB (Tape Automated Bonding) technique are widely used as the circuit boards incorporating the gate drivers and the circuit boards incorporating the source drivers. Examples of the flexible circuit boards include a TCP (Tape Carrier Package) and a COF (Chip On Film). These circuit boards include input electrode terminals for receiving the signals from the outside, and output electrode terminals for sending the signals generated by the gate drivers or the source drivers to the display panel.

The gate-side common circuit board and the source-side common circuit board each include input connectors for inputting the signals from the outside, and connecting areas. The connecting area of the gate-side common circuit board is an area to which the circuit boards incorporating the gate drivers are to be connected, and the area includes output electrode terminals for sending the signals from the outside to the circuit boards incorporating the gate drivers. The connecting area of the source-side common circuit board is an area to which the circuit boards incorporating the source drivers are to be connected, and the area includes output electrode terminals for sending the signals from the outside to the circuit boards incorporating the source drivers.

The circuit boards incorporating the gate drivers and the circuit boards incorporating the source drivers are connected to predetermined positions of the connecting areas provided to the TFT array substrate of the liquid crystal display panel. Thus, the output electrode terminals of the circuit boards incorporating the gate drivers are electrically connected to the wiring electrode terminals provided to the connecting areas of the TFT array substrate. In a similar manner, the output electrode terminals of the circuit boards incorporating the gate drivers are electrically connected to the wiring electrode terminals provided to the connecting areas of the TFT array substrate.

In the display panel assembly having the configuration described above, the signals from the outside are first sent to the gate-side common circuit board via the input connectors, and then sent to the gate drivers via the electrode terminals of the connecting area of the gate-side common circuit board and via the input electrode terminals of the circuit boards incorporating the gate drivers. Then, the gate drivers generate signals based on the sent signals. The signals generated by the gate drivers are sent to the gate lines via the output electrode terminals of the circuit boards incorporating the gate drivers and via the wiring electrode terminals provided to the connecting areas of the TFT array substrate, and then distributed to the gate electrodes of the switching elements.

In a similar manner, the signals from the outside are first sent to the source-side common circuit board via the input connectors, and then sent to the source drivers via the electrode terminals of the connecting area of the source-side common circuit board and via the input electrode terminals of the circuit boards incorporating the source drivers. Then, the source drivers generate signals based on the sent signals. The signals generated by the source drivers are sent to the source lines via the output electrode terminals of the circuit boards incorporating the source drivers and via the wiring electrode terminals provided to the connecting areas of the TFT array substrate, and then distributed to the source electrodes of the switching elements.

There is another type of display panel assembly that does not include a gate-side common circuit board. This type of display pane assembly has a configuration such that signals from the outside are sent to circuit boards incorporating gate drivers via a source-side common circuit board, via some of circuit boards incorporating the source drivers, and via some lines provided to a TFT array substrate of a display panel. In addition, there is another type of display panel assembly that has a configuration such that signals from the outside are sent to a gate-side common circuit board via a source-side common circuit board.

Conductive materials such as anisotropic conductive films are widely used for the connection between the circuit boards incorporating the gate drivers and the gate-side common circuit board, the connection between the circuit boards incorporating the source drivers and the source-side common circuit board, the connection between the circuit boards incorporating the gate drivers and the TFT array substrate of the liquid crystal display panel, and the connection between the circuit boards incorporating the source drivers and the TFT array substrate of the liquid crystal display panel.

A description of a connecting method with the use of an anisotropic conductive film is provided.

First, an anisotropic conductive film is attached to the connecting area of either one circuit board (the gate-side common circuit board, the source-side common circuit board, or the TFT array substrate of the display panel). The anisotropic conductive film has a given thickness and the shape of a long strip. Both sides in a thickness direction of the anisotropic conductive film are made adhesive. A separator (protection sheet) is attached to one side in the thickness direction of the anisotropic conductive film. Thus, the surface of the anisotropic conductive film where no separator is attached is attached to the surfaces of the connecting area, and then the separator is peeled off.

Then, a portion (portion where the input electrode terminals are provided or a portion where the output electrode terminals are provided) of the other circuit board (the circuit boards incorporating the gate drivers or the circuit boards incorporating the source drivers) is attached to a corresponding portion (portion where the given electrode terminals are provided) of the connecting area of the either one circuit board where the anisotropic conductive film is attached.

Then, heat and pressure are applied to the anisotropic conductive film to the extent that the anisotropic conductive film is not cured (this process is referred to as “pre-bonding”). Thus, the either one circuit board and the other circuit board are pre-bonded. Then, heat and pressure are applied to the anisotropic conductive film again (this process is referred to as “post-bonding”). By the post-bonding, the electrode terminals provided on the connecting area of the either one circuit board and the electrode terminals provided to the other circuit board are electrically connected. Further, strength in connection between the either one circuit board and the other circuit board is gained.

In the process of peeling the separator, a force is also applied to the anisotropic conductive film, the force directing is peeled from the surface of the connecting area. Because of this, if the anisotropic conductive film attached to the surface of the connecting area of the either one circuit board is not sufficiently brought into intimate contact with the surface of the connecting area, there arises a problem that the anisotropic conductive film could be peeled therefrom in that process. In addition, if the anisotropic conductive film is not sufficiently in intimate contact with the surface of the connecting area, there arises a problem that reliability in electrical connection between the electrode terminals provided to the either one circuit board and the electrode terminals provided to the other circuit board could be decreased. In addition, there arises a problem that strength in physical connection between the either one circuit board and the other circuit board could be decreased.

In order to solve these problems, various proposals are made to improve the intimate contact between the anisotropic conductive film and the surface of the connecting area of the circuit board or the display panel, or to improve the strength in connection between the circuit boards. For example, PTL 1 discloses a configuration such that a circuit board (referred to as a “flexible wiring sheet” in PTL 1) that includes a group of electrode terminals (referred to as a “group of wiring terminals” in PTL 1), and island-shaped insulating resin films that are disposed at both ends of the group of electrode terminals. This configuration allows the anisotropic conductive film to be connected to the island-shaped insulating resin films by thermocompression bonding. Thus, strength in connection between the anisotropic conductive film and the connecting area can be improved at both the ends of the group of electrode terminals.

However, it is considered that in the configuration disclosed in PTL 1, the anisotropic conductive film produces no “anchor effect” (or, produces a small “anchor effect”), and accordingly strength in connection between the anisotropic conductive film and the connecting area cannot be improved sufficiently. It is to be noted that the “anchor effect” defines an effect that strength in connection between the anisotropic conductive film and the connecting area is improved because the anisotropic conductive film is made not to be easily peeled from the connecting area by the anisotropic conductive film's biting into surface asperities on the connecting area.

In addition, in the process of attaching the anisotropic conductive film to the surface of the connecting area of the either one circuit board, air could get in between the anisotropic conductive film and the connecting area to produce air bubbles. The anisotropic conductive film is off the surface of the connecting area at the portions where the air bubbles are produced, and thus is unconnected (not in contact) to the surface of the connecting area. Thus, the strength in connection between them is decreased. Because of this, in the process of peeling the separator, the anisotropic conductive film is easily peeled from the surface of the connecting area. In addition, in the pre-bonding process and the post-bonding process, the air bubbles could remain without bursting even under pressure because the air expands by heat, or because the pressure inside the air bubbles increases. The anisotropic conductive film could be unconnected to the surface of the connecting area at the portions where the air bubbles are produced. Thus, reliability in electrical connection could be decreased, or strength in physical connection could be decreased.

### CITATION LIST

### Patent Literature

PTL 1: JP P2008-15403 A

### SUMMARY OF INVENTION

In order to overcome the problems described above, one preferred embodiment of the present invention provides a circuit board that allows a conductive material such as an anisotropic conductive film to improve its connection strength, a connecting structure of circuit boards, and a display panel assembly. Another preferred embodiment of the present invention provides a circuit board that allows an anisotropic conductive film attached thereto to improve an anchor effect, a connecting structure of circuit boards, and a display panel assembly. Another preferred embodiment of the present invention provides a circuit board that prevents air bubbles from being produced between an anisotropic conductive film and the circuit board, a connecting structure of circuit boards, and a display panel assembly.

A preferred embodiment of the present invention provides a circuit board that includes a first area including a predetermined number of electrode terminals, and a second area including a predetermined number of structural members having an island shape, wherein the first area and the second area are aligned in a first direction, wherein at least some of the island-shaped structural members have a size in a direction substantially perpendicular to the first direction that is smaller than a size in the direction substantially perpendicular to the first direction of the second area.

It is preferable that the island-shaped structural members, which have the size in the direction substantially perpendicular to the first direction that is smaller than the size in the direction substantially perpendicular to the first direction of the second area, are aligned in the direction substantially perpendicular to the first direction in the second area.

It is preferable that the island-shaped structural members, which have the size in the direction substantially perpendicular to the first direction that is smaller than the size in the direction substantially perpendicular to the first direction of the second area, are aligned in a zigzag arrangement in the direction substantially perpendicular to the first direction in the second area.

It is preferable that the island-shaped structural members, which have the size in the direction substantially perpendicular to the first direction that is smaller than the size in the direction substantially perpendicular to the first direction of the second area, are aligned in a direction inclined predetermined angles toward the first direction in the second area.

It is preferable that the island-shaped structural members, which have the size in the direction substantially perpendicular to the first direction that is smaller than the size in the direction substantially perpendicular to the first direction of the second area, are aligned in a random fashion in the second area.

It is preferable that each of the island-shaped structural members, which have the size in the direction substantially perpendicular to the first direction that is smaller than the size in the direction substantially perpendicular to the first direction of the second area, includes main bodies, each of which has a predetermined overall size, and connecting portions, each of which has a width that is smaller than the overall size of each main body, the connecting portions connecting the main bodies.

It is preferable that the island-shaped structural members are made from a conductor film same as a conductor film from which the electrode terminals are made.

It is preferable that the island-shaped structural members are made from a photoresist material.

It is preferable that the island-shaped structural members are made from an ink.

It is preferable that the first area includes a plurality of first areas that are aligned in the first direction, and the second area includes a plurality of second areas, wherein the second areas are disposed between the first areas.

It is preferable that the first area includes a plurality of first areas that are aligned in the first direction, and the second area includes a plurality of second areas, wherein the second areas are disposed in the first direction adjacent to the first areas. In this case, the second areas are preferably disposed in the first direction on both adjacent sides of the first areas.

It is preferable that the first area includes a plurality of first areas that are aligned in the first direction, and the second area includes a plurality of second areas, wherein the second areas are disposed in the first direction outside of the first areas disposed at the ends of the circuit board.

It is preferable that the first area includes a plurality of first areas that are aligned in the first direction, and the second area includes a plurality of second areas, wherein at least two of the second areas are disposed at predetermined intervals in the first direction, wherein the first areas are disposed in the first direction between the second areas.

In another aspect of the present invention, a circuit board that is capable of being connected to another circuit board with the use of a conductive material having the shape of a long strip includes a first area including a predetermined number of electrode terminals, and a second area including a predetermined number of structural members having an island shape, wherein the first area and the second area are aligned in a first direction, wherein at least some of the island-shaped structural members have a size in a direction substantially perpendicular to the first direction that is smaller than a width of the long strip-shaped conductive material.

It is preferable that the island-shaped structural members, which have the size in the direction substantially perpendicular to the first direction that is smaller than the width of the long strip-shaped conductive material, are aligned in the direction substantially perpendicular to the first direction in the second area.

It is preferable that the island-shaped structural members, which have the size in the direction substantially perpendicular to the first direction that is smaller than the width of the long strip-shaped conductive material, are aligned in a zigzag arrangement in the direction substantially perpendicular to the first direction in the second area.

It is preferable that the island-shaped structural members, which have the size in the direction substantially perpendicular to the first direction that is smaller than the width of the long strip-shaped conductive material, are aligned in a direction inclined predetermined angles toward the first direction in the second area.

It is preferable that the island-shaped structural members, which have the size in the direction substantially perpendicular to the first direction that is smaller than the width of the long strip-shaped conductive material, are aligned in a random fashion in the second area.

It is preferable that each of the island-shaped structural members, which have the size in the direction substantially perpendicular to the first direction that is smaller than the width of the long strip-shaped conductive material, includes main bodies, each of which has a predetermined overall size, and connecting portions, each of which has a width that is smaller than the overall size of each main body, the connecting portions connecting the main bodies.

It is preferable that the island-shaped structural members are made from a conductor film same as a conductor film from which the electrode terminals are made.

It is preferable that the island-shaped structural members are made from a photoresist material.

It is preferable that the island-shaped structural members are made from an ink.

It is preferable that the first area includes a plurality of first areas that are aligned in the first direction, and the second area includes a plurality of second areas, wherein the second areas are disposed between the first areas.

It is preferable that the first area includes a plurality of first areas that are aligned in the first direction, and the second area includes a plurality of second areas, wherein the second areas are disposed in the first direction adjacent to the first areas.

It is preferable that the second areas are disposed on both adjacent sides of the first areas.

It is preferable that the first area includes a plurality of first areas that are aligned in the first direction, and the second area includes a plurality of second areas, wherein the second areas are disposed in the first direction outside of the first areas disposed at the ends of the circuit board.

It is preferable that the first area includes a plurality of first areas that are aligned in the first direction, and the second area includes a plurality of second areas, wherein at least two of the second areas are disposed at predetermined intervals in the first direction, wherein the first areas are disposed in the first direction between the second areas.

Yet, in another aspect of the present invention, a connecting structure of the circuit board that is connected to another circuit board including a predetermined number of electrode terminals with the use of a conductive material is characterized in that the predetermined number of electrode terminals on the first area of the circuit board are opposed, sandwiching the conductive material, to the corresponding electrode terminals on the another circuit board, wherein the conductive material covers at least a portion of the second area of the circuit board, whereby the conductive material covers entire surfaces of the island-shaped structural members, which have the size in the direction substantially perpendicular to the first direction that is smaller than the size in the direction substantially perpendicular to the first direction of the second area.

Yet, in another aspect of the present invention, a connecting structure of the circuit board that is connected to another circuit board including a predetermined number of electrode terminals with the use of a conductive material is characterized in that the predetermined number of electrode terminals on the first area of the circuit board are opposed, sandwiching the conductive material, to the corresponding electrode terminals on the another circuit board, wherein the conductive material covers at least a portion of the second area of the circuit board according to any one of claims 15 to 23, whereby the conductive material covers entire surfaces of the island-shaped structural members, which have the size in the direction substantially perpendicular to the first direction that is smaller than the size in the direction substantially perpendicular to the first direction of the second area.

It is preferable that a size in the direction substantially perpendicular to the first direction of the conductive material is larger than the size in the direction substantially perpendicular to the first direction of the second area, wherein the second area includes a portion that is covered over the entire length in the direction substantially perpendicular to the first direction with the conductive material.

It is preferable that the conductive material includes an anisotropic conductive film.

It is preferable that the anisotropic conductive film has the shape of a long strip, and has a width that is larger than the size in the direction substantially perpendicular to the first direction of the second area, wherein the anisotropic conductive film is attached to the first area and the second area with its longer direction in the first direction so as to straddle an entire surface of the first area and at least a portion of the second area.

Yet, in another aspect of the present invention, a display panel assembly includes a display panel, a first circuit board including a predetermined number of electrode terminals, which is connected to the display panel, a second circuit board connected to the first circuit board, the second circuit board including a first area including a predetermined number of electrode terminals, and a second area including a predetermined number of structural members having an island shape, wherein the first area and the second area are aligned in a first direction, wherein at least some of the island-shaped structural members have a size in a direction substantially perpendicular to the first direction that is smaller than a size in the direction substantially perpendicular to the first direction of the second area, wherein a conductive material is attached to the first area and the second area so as to straddle an entire surface of the first area and at least a portion of the second area, wherein the electrode terminals on the first circuit board are opposed, sandwiching the conductive material, to the predetermined number of corresponding electrode terminals on the first area of the second circuit board, wherein the conductive material covers entire surfaces of the island-shaped structural members, which have the size in the direction substantially perpendicular to the first direction that is smaller than the size in the direction substantially perpendicular to the first direction of the second area.

It is preferable that the island-shaped structural members, which have the size in the direction substantially perpendicular to the first direction that is smaller than the size in the direction substantially perpendicular to the first direction of the second area, are aligned in the direction substantially perpendicular to the first direction in the second area of the second circuit board.

It is preferable that the island-shaped structural members, which have the size in the direction substantially perpendicular to the first direction that is smaller than the size in the direction substantially perpendicular to the first direction of the second area, are aligned in a zigzag arrangement in the direction substantially perpendicular to the first direction in the second area of the second circuit board.

It is preferable that the island-shaped structural members, which have the size in the direction substantially perpendicular to the first direction that is smaller than the size in the direction substantially perpendicular to the first direction of the second area, are aligned in a direction inclined predetermined angles toward the first direction in the second area of the second circuit board.

It is preferable that the island-shaped structural members, which have the size in the direction substantially perpendicular to the first direction that is smaller than the size in the direction substantially perpendicular to the first direction of the second area, are aligned in a random fashion in the second area of the second circuit board.

It is preferable that each of the island-shaped structural members, which have the size in the direction substantially perpendicular to the first direction that is smaller than the size in the direction substantially perpendicular to the first direction of the second area, includes main bodies, each of which has a predetermined overall size, and connecting portions, each of which has a width that is smaller than the overall size of each main body, the connecting portions connecting the main bodies.

Yet, in another aspect of the present invention, a display panel assembly includes a display panel, a first circuit board including a predetermined number of electrode terminals, which is connected to the display panel, a second circuit board connected to the first circuit board with the use of a conductive material having the shape of a long strip, the second circuit board including a first area including a predetermined number of electrode terminals, and a second area including a predetermined number of structural members having an island shape, wherein the first area and the second area are aligned in a first direction, wherein at least some of the island-shaped structural members have a size in a direction substantially perpendicular to the first direction that is smaller than a width of the long strip-shaped conductive material, wherein the long strip-shaped conductive material is attached to the first area and the second area so as to straddle an entire surface of the first area and at least a portion of the second area, wherein the electrode terminals on the first circuit board are opposed, sandwiching the conductive material, to the predetermined number of corresponding electrode terminals on the first area of the second circuit board, wherein the conductive material covers entire surfaces of the island-shaped structural members, which have the size in the direction substantially perpendicular to the first direction that is smaller than the width of the long strip-shaped conductive material.

It is preferable that the island-shaped structural members, which have the size in the direction substantially perpendicular to the first direction that is smaller than the width of the long strip-shaped conductive material, are aligned in the direction substantially perpendicular to the first direction in the second area of the second circuit board.

It is preferable that the island-shaped structural members, which have the size in the direction substantially perpendicular to the first direction that is smaller than the size in the direction substantially perpendicular to the first direction of the second area, are aligned in a zigzag arrangement in the direction substantially perpendicular to the first direction in the second area of the second circuit board.

It is preferable that the island-shaped structural members, which have the size in the direction substantially perpendicular to the first direction that is smaller than the size in the direction substantially perpendicular to the first direction of the second area, are aligned in a direction inclined predetermined angles toward the first direction in the second area of the second circuit board.

It is preferable that the island-shaped structural members, which have the size in the direction substantially perpendicular to the first direction that is smaller than the size in the direction substantially perpendicular to the first direction of the second area, are aligned in a random fashion in the second area of the second circuit board.

It is preferable that each of the island-shaped structural members, which have the size in the direction substantially perpendicular to the first direction that is smaller than the width of the long strip-shaped conductive material, includes main bodies, each of which has a predetermined overall size, and connecting portions, each of which has a width that is smaller than the overall size of each main body, the connecting portions connecting the main bodies.

It is preferable that in the second circuit board, the first area includes a plurality of first areas that are aligned in the first direction, and the second area includes a plurality of second areas, wherein the second areas are disposed between the first areas, wherein a conductive material is attached to the first areas and the second areas so as to straddle the first areas and the second areas, wherein the first circuit board includes a plurality of first circuit boards that are connected to the corresponding first areas of the second circuit board with the use of the conductive material.

It is preferable that in the second circuit board, the first area includes a plurality of first areas that are aligned in the first direction, and the second area includes a plurality of second areas that are disposed in the first direction adjacent to the first areas, wherein conductive materials are attached to the first areas and the second areas so as to straddle the first areas and the second areas adjacent to the first areas, wherein the first circuit board includes a plurality of first circuit boards that are connected to the corresponding first areas of the second circuit board.

It is preferable that, in the first circuit board, the second areas are disposed in the first direction on both adjacent sides of the first areas in the first circuit board, wherein the conductive materials are attached to the first areas and the second areas so as to straddle the first areas and the second areas adjacent to the first areas.

It is preferable that, in the first circuit board, the first area includes a plurality of first areas that are aligned in the first direction, and the second area includes a plurality of second areas, wherein the second areas are disposed in the first direction outside of the first areas disposed at the ends of the circuit board, wherein a conductive material is attached over the entire length between the second areas.

It is preferable that, in the circuit board, the second area includes at least two second areas disposed in the first direction at predetermined intervals, and the first area includes a plurality of first areas disposed in the first direction between the second areas, wherein a conductive material is attached over the entire length between the at least two second areas.

The circuit board of the preferred embodiments of the present invention is capable of obtaining an anchor effect with the use of the island-shaped structural members provided on the second area when a conductive material such as an anisotropic conductive film is attached to the circuit board so as to straddle the first area and the second area. With this configuration, the contact of a surface of the second area to the conductive material such as the anisotropic conductive film is improved, which accordingly improves strength in connection between the surface of the second area and the conductive material such as the anisotropic conductive film. Thus, in the process of peeling a separator from the conductive material such as the anisotropic conductive film, the conductive material such as the anisotropic conductive film is prevented from being peeled from the surfaces of the first and second areas.

In addition, the configuration of the circuit board of the preferred embodiments of the present invention that some island-shaped structural members have the size (width) in the direction substantially perpendicular to the first direction that is smaller than the size in the direction substantially perpendicular to the first direction of the second area allows air to flow even when the conductive material such as the anisotropic conductive film is attached to the circuit board over the entire length in a width direction of the second area.

To be specific, if the width of each island-shaped structural member is same or larger than the width of the first area, the air gotten in between the conductive material such as the anisotropic conductive film and the surface of the second area can only flow in the width direction. Thus, if the conductive material such as the anisotropic conductive film is attached to the surface of the second area at both ends in the width direction of the second area, air cannot flow, which could produce air bubbles.

In contrast, the configuration of the circuit board of the preferred embodiments of the present invention that some island-shaped structural members have the size smaller than the size in the width direction of the second area allows the air gotten in between the conductive material such as the anisotropic conductive film and the second area to move in the first direction. Thus, an “air escape way” can be provided, which can prevent air bubbles from being produced between the conductive material such as the anisotropic conductive film and the surface of the second area.

The same action and effect as those obtained in the configuration described above can be obtained also by a circuit board having a configuration such that some island-shaped structural members have a size smaller than the width of the conductive material such as the anisotropic conductive film.

Thus, the connecting structure of the circuit boards of the preferred embodiments of the present invention allows reliability in electrical connection between the circuit boards to be improved, and further allows strength in physical connection between the circuit boards to be improved, or prevents strength in physical connection between the circuit boards from being decreased.

Thus, the configuration of the display panel assembly of the preferred embodiments of the present invention allows reliability in electrical connection between the circuit boards connected to the display panel to be improved, and further allows strength in physical connection between the circuit boards to be improved, or prevents strength in physical connection between the circuit boards from being decreased. Thus, a display panel assembly of high quality can be achieved.

### BRIEF DESCRIPTION OF DRAWINGS

FIG. 1 is an external perspective view schematically showing a configuration of a circuit board of one of preferred embodiments of the present invention.

FIGS. 2A and 2B are partial plan views of the circuit board of the preferred embodiment of the present invention, where the view shown in FIG. 2A schematically shows a configuration of a connecting area of the circuit board, and the view shown in FIG. 2B schematically shows a configuration of an island-shaped structural member.

FIGS. 3A, 3B, 3C and 3D are views showing modified shapes of the island-shaped structural members.

FIG. 4 is a partial plan view of the connecting area of the circuit board of the preferred embodiment of the present invention, which schematically shows modified alignment of the island-shaped structural members.

FIG. 5 is a partial plan view of the connecting area of the circuit board of the preferred embodiment of the present invention, which schematically shows modified alignment of the island-shaped structural members.

FIG. 6 is a partial plan view of the connecting area of the circuit board of the preferred embodiment of the present invention, which schematically shows modified alignment of the island-shaped structural members.

FIG. 7 is a partial plan view of the connecting area of the circuit board of the preferred embodiment of the present invention, which schematically shows modified alignment of the island-shaped structural members.

FIGS. 8A and 8B are plan views showing a modified configuration of island-shaped structural members, where shown in FIG. 8A is a partial view of the connecting area of the circuit board of the preferred embodiment of the present invention, and shown in FIG. 8B is an enlarged view schematically showing the modified configuration of the island-shaped structural members.

FIGS. 9A and 9B are plan views schematically showing relations between the size of a conductive material having a sheet shape that is attached to the connecting area of the circuit board of the preferred embodiment of the present invention, and the sizes of the connecting area and the island-shaped structural members, where shown in FIG. 9A is the sheet-shaped conductive material attached to the connecting area, the conductive material having the size that is smaller than the size in a second direction of the connecting area, and shown in FIG. 9B is the sheet-shaped conductive material attached to the connecting area, the conductive material having the size that is larger than the size in the second direction of the connecting area.

FIGS. 10A, 10B, 10C and 10D are plan views schematically showing modified configurations of the island-shaped structural members, and modified alignment of the island-shaped structural members.

FIGS. 11A, 11B, 11C and 11D are plan views schematically showing modified configurations of the island-shaped structural members, and modified alignment of the island-shaped structural members.

FIGS. 12A, 12B, 12C and 12D are plan views schematically showing modified configurations of the island-shaped structural members, and modified alignment of the island-shaped structural members.

FIGS. 13A, 13B, 13C and 13D are plan views schematically showing modified configurations of the island-shaped structural members, and modified alignment of the island-shaped structural members.

FIGS. 14A, 14B, 14C and 14D are plan views schematically showing modified configurations of the island-shaped structural members, and modified alignment of the island-shaped structural members.

FIG. 15 is an exploded perspective view schematically showing a connecting method and a connecting structure between the circuit board of the preferred embodiment of the present invention and another circuit board, where the circuit boards are yet to be connected.

FIG. 16 is a cross-sectional view schematically showing the connecting structure between the circuit board of the preferred embodiment of the present invention and the another circuit board, where the circuit boards are connected.

FIG. 17 is an external perspective view schematically showing a configuration of a display panel assembly of one of preferred embodiments of the present invention.

FIG. 18 is an external perspective view schematically showing a configuration of a second circuit board on a source side of a first preferred embodiment of the present invention.

FIG. 19 is an exploded perspective view schematically showing a connecting method and a connecting structure between the source-side second circuit board of the first preferred embodiment of the present invention and first circuit boards incorporating source drivers, where the circuit boards are yet to be connected.

FIG. 20 is an exploded perspective view schematically showing the connecting method and the connecting structure between the source-side second circuit board of the first preferred embodiment of the present invention and the first circuit boards incorporating the source drivers, where the circuit boards are connected.

FIG. 21 is an exploded perspective view schematically showing a connecting method and a connecting structure between the source-side second circuit board of the first preferred embodiment of the present invention and the first circuit boards incorporating the source drivers with the use of anisotropic conductive films, where the circuit boards are yet to be connected.

FIG. 22 is an exploded perspective view schematically showing the connecting method and the connecting structure between the source-side second circuit board of the first preferred embodiment of the present invention and the first circuit boards incorporating the source drivers with the use of the anisotropic conductive films, where the circuit boards are connected.

FIG. 23 is an external perspective view schematically showing a configuration of a second circuit board on a source side of a second preferred embodiment of the present invention.

FIG. 24 is an exploded perspective view schematically showing a connecting method and a connecting structure between the source-side second circuit board of the second preferred embodiment of the present invention and the first circuit boards incorporating the source drivers, where the circuit boards are yet to be connected.

FIG. 25 is an exploded perspective view schematically showing the connecting method and the connecting structure between the source-side second circuit board of the second preferred embodiment of the present invention and the first circuit boards incorporating the source drivers, where the circuit boards are connected.

FIG. 26 is an exploded perspective view schematically showing a connecting method and a connecting structure between the source-side second circuit board of the second preferred embodiment of the present invention and the first circuit boards incorporating the source drivers with the use of conductive materials having a sheet shape, where the circuit boards are yet to be connected.

FIG. 27 is an exploded perspective view schematically showing the connecting method and the connecting structure between the source-side second circuit board of the second preferred embodiment of the present invention and the first circuit boards incorporating the source drivers with the use of the sheet shaped conductive materials, where the circuit boards are connected.

FIG. 28 is an external perspective view schematically showing a configuration of a second circuit board on a source side of a third preferred embodiment of the present invention.

FIG. 29 is an exploded perspective view schematically showing a connecting method and a connecting structure between the source-side second circuit board of the third preferred embodiment of the present invention and the first circuit boards incorporating the source drivers, where the circuit boards are yet to be connected.

FIG. 30 is an exploded perspective view schematically showing the connecting method and the connecting structure between the source-side second circuit board of the third preferred embodiment of the present invention and the first circuit boards incorporating the source drivers, where the circuit boards are connected.

### DETAILED DESCRIPTION OF THE INVENTION

Detailed descriptions of preferred embodiments of the present invention will now be provided with reference to the accompanying drawings.

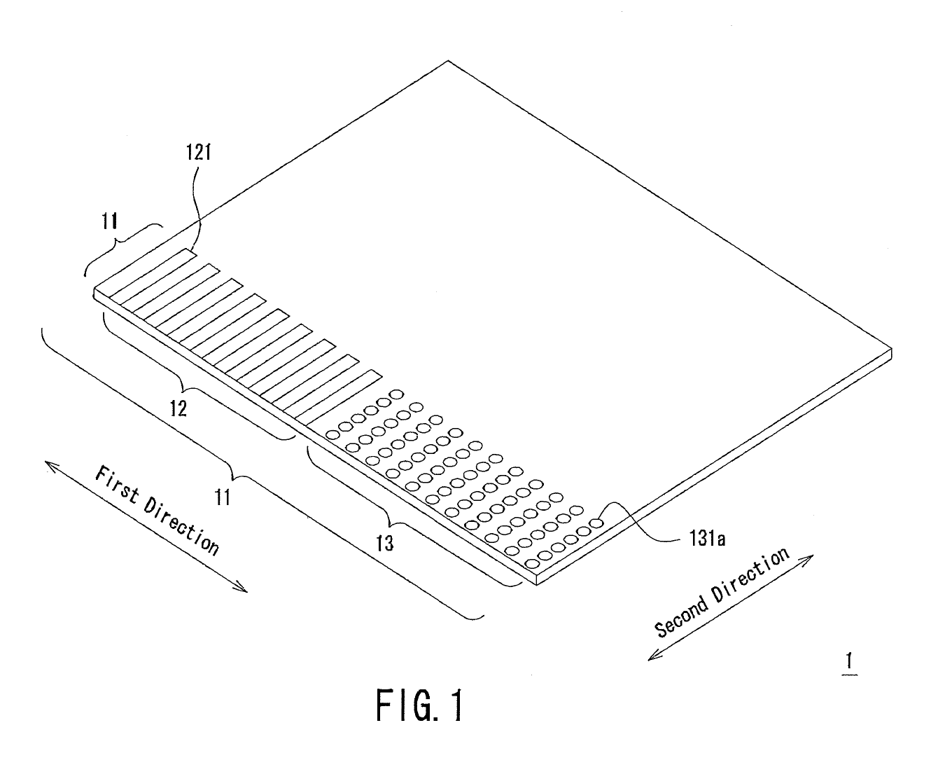

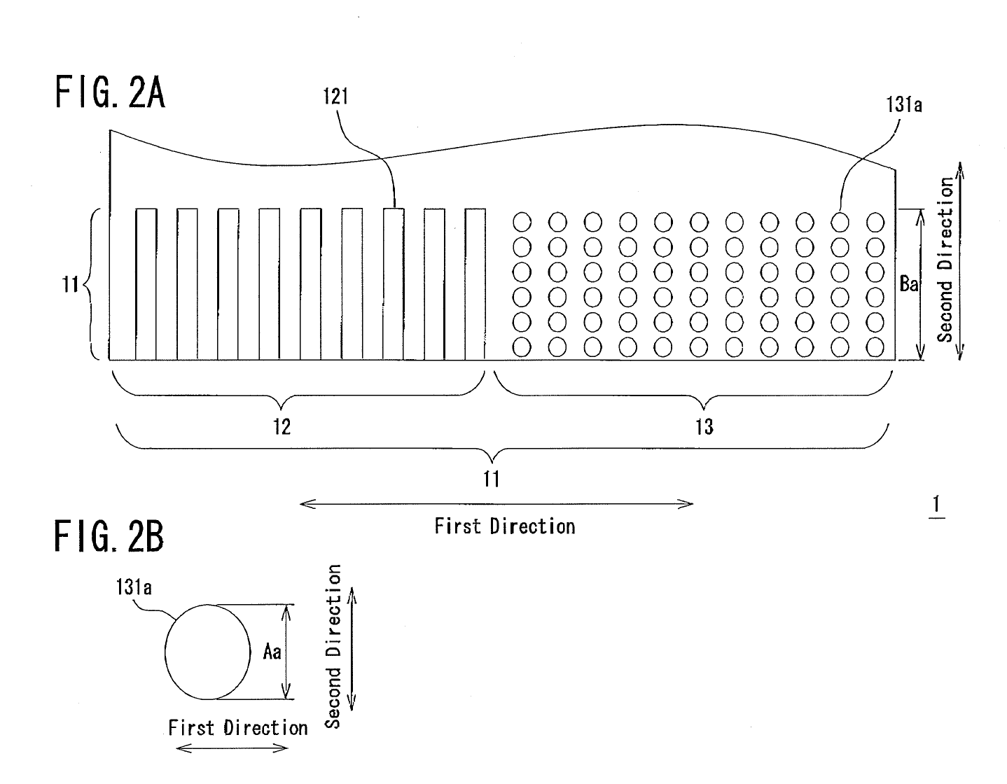

FIG. 1 is an external perspective view schematically showing a configuration of a circuit board 1 of one of the preferred embodiments of the present invention. FIGS. 2A and 2B are partial plan views of the circuit board 1 of the preferred embodiment of the present invention, where the view shown in FIG. 2A schematically shows a configuration of a connecting area 11, and the view shown in FIG. 2B schematically shows a configuration of one of structural members 131a having an island shape.

As shown in FIGS. 1 and 2A, the circuit board 1 includes the connecting area 11. In addition, the circuit board 1 includes given lines and given constituent elements, which are not shown in FIG. 1.

A conductive material having a sheet shape such as an anisotropic conductive film (ACF) is to be attached to the connecting area 11 so that the circuit board 1 of the preferred embodiment of the present invention is connected to another circuit board. The connecting area 11 includes a first area 12 and a second area 13, that are aligned in a first direction.

The first area 12 includes a given number of electrode terminals 121. The electrode terminals 121 are electrically connected to electrode terminals of the another circuit board, which allows transmission of signals between the circuit board 1 and the another circuit board. The configuration of the electrode terminals 121 is not limited specifically. The electrode terminals 121 are preferably made from a conductor film, each of which has a rectangular shape that is longer in a direction perpendicular to the first direction (hereinafter, referred to as the “second direction) (i.e., a rectangular shape, the longer side of which is substantially parallel to the second direction) as shown in FIGS. 1 and 2A. The electrode terminals 121 are aligned in the first direction on the first area 12. The electrode terminals 121 are electrically connected to the lines and the constituent elements provided to the circuit board 1. The electrode terminals 121 are formed by subjecting a conductor film (e.g., a film made from copper) formed on the circuit board 1 to pattering such as etching.

The second area 13 includes the given number of island-shaped structural members 131a. The island-shaped structural members 131a are provided in order to prevent the sheet-shaped conductive material such as the anisotropic conductive film that is attached to the surface of the connecting area 11 from being peeled therefrom. The island-shaped structural members 131a have a given thickness. The island-shaped structural members 131a formed on the second area 13 form surface asperities on the second area 13. To be specific, the island-shaped structural members 131a form convex portions, and the other portions on the second area 13 (e.g., the spaces between the island-shaped structural members 131a) form concave portions.

As shown in FIGS. 2A and 2B, all or some of the island-shaped structural members 131a have a size Aa in the second direction that is smaller than a size Ba in the second direction of the connecting area 11 (i.e., a size in the second direction of the second area 13). For example, when the island-shaped structural members 131a have a round shape as shown in FIGS. 1 and 2A, the diameter of each island-shaped structural member 131a is smaller than the size Ba in the second direction of the connecting area 11. Shown in FIGS. 1 and 2A is an example that the sizes Aa in the second direction of all the island-shaped structural members 131a are smaller than the size Ba in the second direction of the connecting area 11. It is also preferable that the sizes Aa in the second direction of some of the island-shaped structural members 131a are same or larger than the size Ba in the second direction of the connecting area 11.

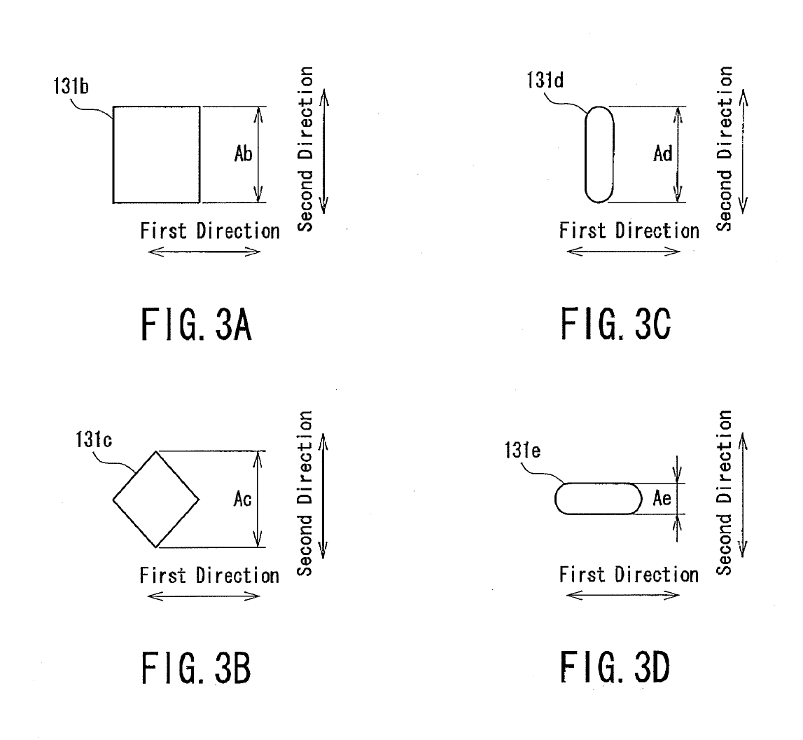

The shape of island-shaped structural members provided to the second area 13 of the connecting area 11 is not limited to the round shape shown in FIGS. 1, 2A and 2B. FIGS. 3A, 3B, 3C and 3D are views showing modified shapes of the island-shaped structural members. To be specific, shown in FIG. 3A is an island-shaped structural member 131b that has a quadrilateral shape, where two sides of the square are substantially parallel to the first direction and the other two sides are substantially parallel to the second direction. Shown in FIG. 3B is an island-shaped structural member 131c that has the shape of a parallelogram, where the four sides of the parallelogram are inclined given angles toward the first direction the second direction. Shown in FIG. 3C is an island-shaped structural member 131d that has an oval shape, where the long axis of the oval is substantially parallel to the second direction. Shown in FIG. 3D is an island-shaped structural member 131e that has an oval shape, where the long axis of the oval is substantially parallel to the first direction.

At least some of the island-shaped structural members 131b, 131c, 131d and 131e respectively have sizes Ab, Ac, Ad and Ae in the second direction that are smaller than the size Ba in the second direction of the connecting area 11.

Thus, the island-shaped structural members 131a, 131b, 131c, 131d and 131e those having the sizes described above (the island-shaped structural members having the sizes in the second direction smaller than the size in the second direction of the connecting area 11 (i.e., the size in the second direction of the second area 13)) are provided in a given arrangement on the second area 13 of the connecting area 11. For example, the island-shaped structural members 131a having the round shape and the size described above are provided in a matrix arrangement as shown in FIGS. 1 and 2A. The island-shaped structural members 131b, 131c, 131d and 131e of modified shapes shown in FIGS. 3A, 3B, 3C and 3D are also preferably provided in given arrangements.

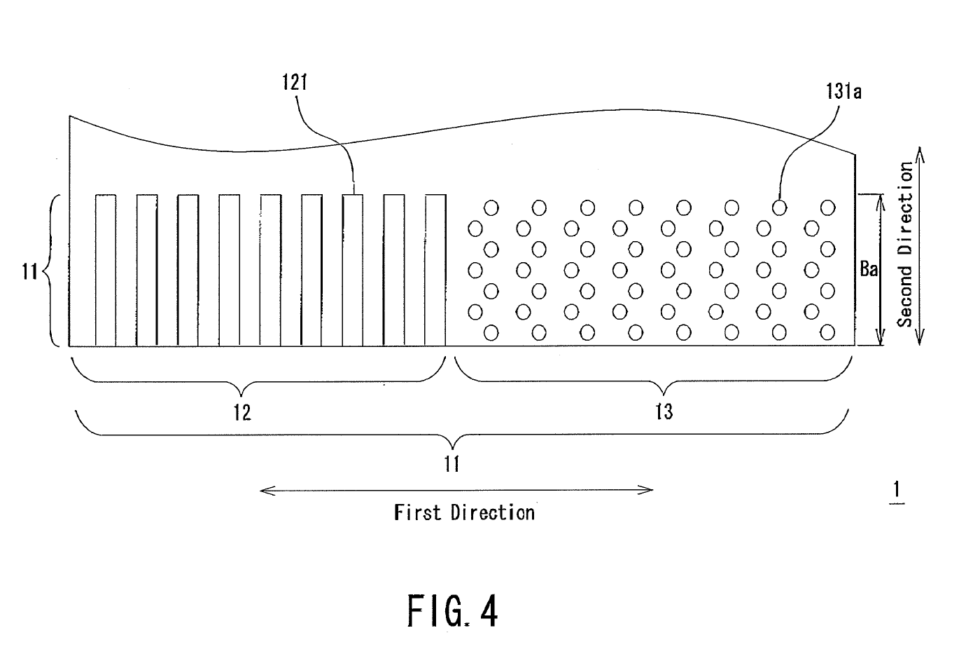

The arrangements in which the island-shaped structural members 131a, 131b, 131c, 131d and 131e are provided are not limited to the arrangement shown in FIGS. 1 and 2A. Hereinafter, descriptions of modified alignment of the island-shaped structural members 131a, 131b, 131c, 131d and 131e are provided. FIGS. 4, 5, 6 and 7 are partial plan view of the connecting area 11 of the circuit board 1 of the preferred embodiment of the present invention, which schematically shows the modified alignment of the island-shaped structural members 131a, 131b, 131c, 131d and 131e.

On the second area 13 of the connecting area 11 of the circuit board 1 shown in FIG. 4, the island-shaped structural members 131a having the size described above are aligned in a zigzag arrangement in the second direction, and the island-shaped structural members 131a in the zigzag arrangement are aligned in the first direction.

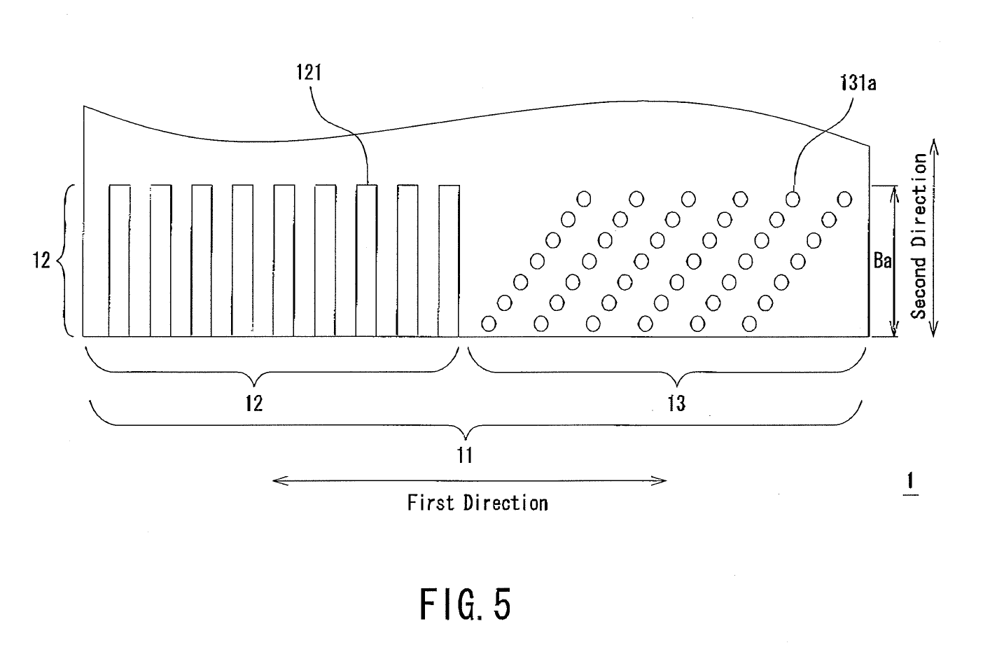

On the second area 13 of the connecting area 11 of the circuit board 1 shown in FIG. 5, the island-shaped structural members 131a having the size described above are aligned in a direction inclined given angles toward the first direction, and the island-shaped structural members 131a are aligned in the first direction.

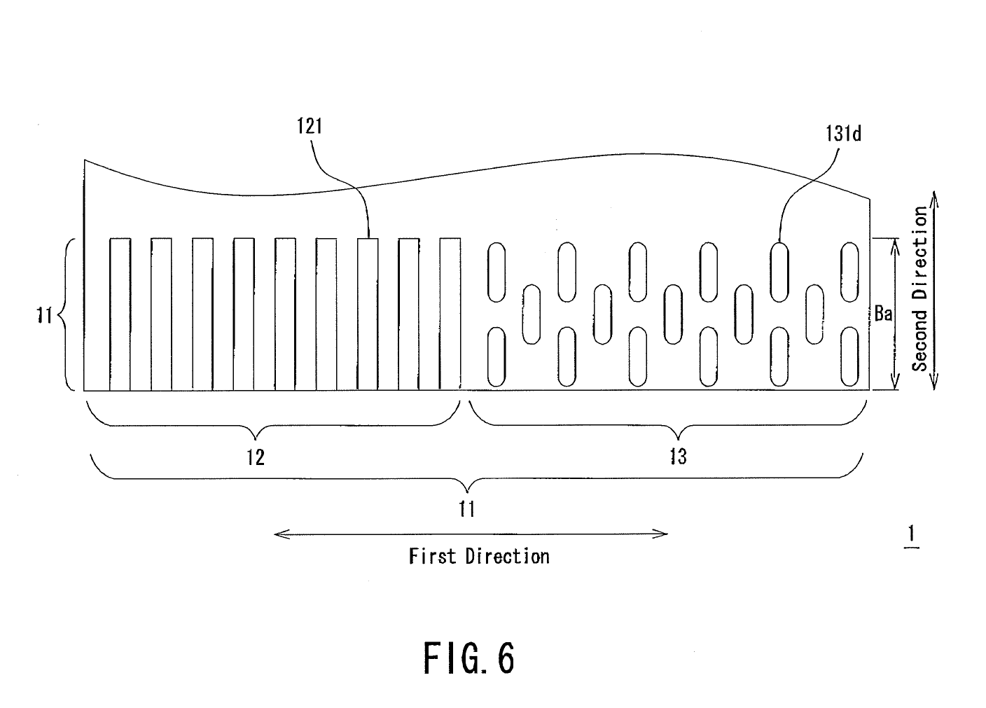

On the second area 13 of the connecting area 11 of the circuit board 1 shown in FIG. 6, the connecting area 11 includes portions where the two island-shaped structural members 131d having the size described above are aligned in the second direction, and portions where the one island-shaped structural member 131d having the size described above is aligned in the second direction, where the two kinds of portions are aligned alternately in the first direction.

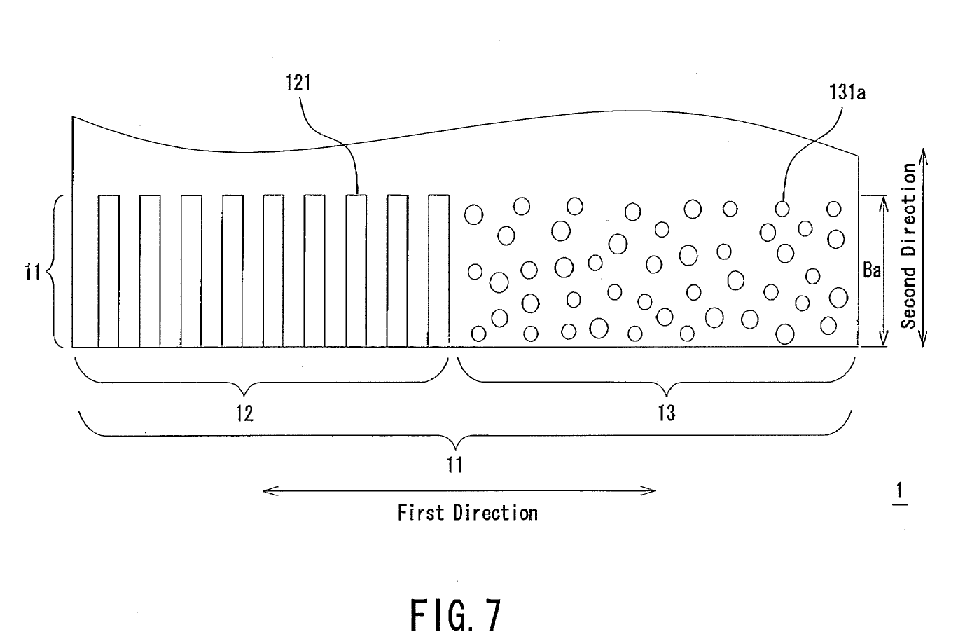

On the second area 13 of the connecting area 11 of the circuit board 1 shown in FIG. 7, the island-shaped structural members 131a having the size described above are aligned in a random fashion.

Shown in FIGS. 4, 5 and 7 are the configurations including the island-shaped structural members 131a having the round shape, and shown in FIG. 6 is the configuration including the island-shaped structural members 131d having the oval shape of which the long axis is substantially parallel to the second direction. The configurations are only examples, and the shape of the island-shaped structural members is not limited specifically.

As described above, the circuit board 1 includes the island-shaped structural members 131a, 131b, 131c, 131d or 131e having the sizes described above that are provided in the given arrangements on the second area 13 of the connecting area 11. It is preferable that the island-shaped structural members 131a, 131b, 131c, 131d or 131e having the sizes described above are aligned in the second direction. To be specific, it is preferable that the island-shaped structural members 131a, 131b, 131c, 131d and 131e having the sizes described above are aligned such that a straight line, if drawn in the second direction in the second area 13, may cut across the island-shaped structural members 131a, 131b, 131c, 131d and 131e. In FIGS. 1, 2A, 4, 5, 6 and 7, the island-shaped structural members 131a, 131b, 131c, 131 and 131e having the sizes described above are aligned such that a straight line, if drawn in the second direction in the second area 13, may cut across the island-shaped structural members 131a, 131b, 131c, 131d and 131e.

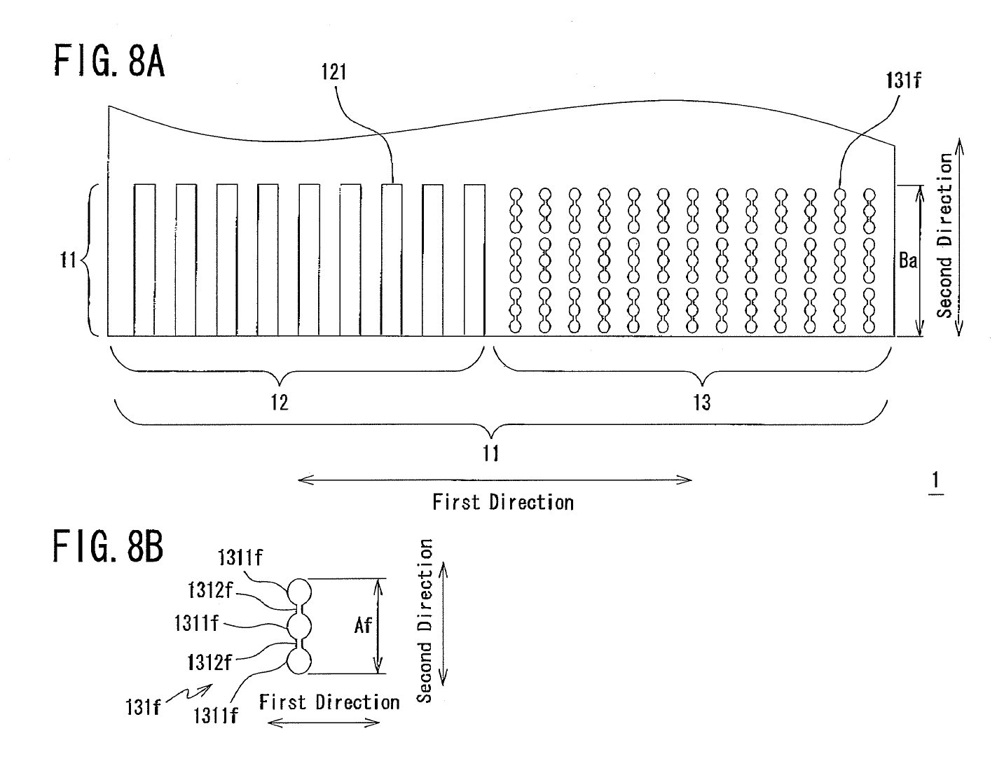

Next, a description of a modified configuration of the island-shaped structural members is provided. The island-shaped structural members having the modified configuration are capable of improving their strength of resistance against peeling from the surface of the second area 13 of the connecting area 11 of the circuit board 1. FIGS. 8A and 8B are plan views showing a modified configuration of island-shaped structural members 131f having the size described above, where shown in FIG. 8A is a partial view of the connecting area 11 of the circuit board 1, and shown in FIG. 8B is an enlarged view schematically showing the modified configuration of the island-shaped structural members 131f.

Each island-shaped structural member 131f shown in FIGS. 8A and 8B includes main bodies 1311f, and connecting portions 1312f arrange to connect the main bodies 1311f. Each connecting portion 1312f has a width that is smaller than the overall size of each main body 1311f. The main bodies 1311f and the connecting portions 1312f of each island-shaped structural member 131f are of a monolithic construction made from a same material.

Shown in FIGS. 8A and 8B are the island-shaped structural members 131f, each of which includes the three main bodies 1311f that are aligned, and the two connecting portions 1312f that connect the three main bodies 1311f; however, the number of main bodies 1311f is not limited specifically. It is also preferable that each island-shaped structural member 131f includes the two main bodies 1311f, and the one connecting portion 1312f arranged to connect the two main bodies 1311f. It is also preferable that each island-shaped structural member 131f includes the four or more main bodies 1311f. In addition, the shape of the main bodies 1311f is not limited to the round shape, and the main bodies 1311f may have a variety of shapes. Examples of the shape of the main bodies 1311f include the shapes of the island-shaped structural members 131b, 131c, 131d and 131e shown in FIGS. 3A, 3B, 3C and 3D.

In addition to the configuration that the main bodies 1311f are aligned, it is preferable that the main bodies 1311f are aligned in a zigzag arrangement. It is essential only that the main bodies 1311f should be connected by the connecting portions 1312f having the width that is smaller than the overall size of each main body 1311f.

The island-shaped structural members 131f are aligned on the second area 13 of the connecting area 11 as shown in FIG. 8A. At least some of the island-shaped structural members 131f have a size Aa in the second direction that is smaller than a size Ba in the second direction of the connecting area 11. Shown in FIG. 8A is an example that the sizes Aa in the second direction of all the island-shaped structural members 131f are smaller than the size Ba in the second direction of the connecting area 11. In addition, the island-shaped structural members 131f may be aligned in a variety of fashions in addition to the matrix arrangement shown in FIG. 8A. For example, the island-shaped structural members 131f may be aligned in the fashions shown in FIGS. 4, 5, 6 and 7.

The island-shaped structural members 131f having the modified configuration are capable of improving their strength of resistance against peeling from the surface of the second area 13 of the connecting area 11.

To be specific, when a poor connection is found between the circuit board 1 and the another circuit board, the attachment of the sheet-shaped conductive material and the connection to the another circuit board are sometimes redone. In advance of the redo, the sheet-shaped conductive material attached to the surface of the connecting area 11 needs to be peeled therefrom. Because the sheet-shaped conductive material is attached also to the surfaces of the island-shaped structural members 131a, 131b, 131c, 131d, 131e or 131f, a force such as to peel the island-shaped structural members 131a, 131b, 131c, 131d, 131e or 131f from the surface of the second area 13 of the connecting area 11 is applied also to the island-shaped structural members 131a, 131b, 131c, 131d, 131e or 131f. For this reason, if connection strength of the island-shaped structural members 131a, 131b, 131c, 131d, 131e or 131f to the surface of the second area 13 of the connecting area 11 is weaker than connection strength of the island-shaped structural members 131a, 131b, 131c, 131d, 131e or 131f to the sheet-shaped conductive material, the island-shaped structural members 131a, 131b, 131c, 131d, 131e or 131f could be peeled from the surface of the second area 13 of the connecting area 11.

Because the island-shaped structural members 131f having the modified configuration has the configuration that the main bodies 1311f are connected with each other by the connecting portions 1312f and accordingly the main bodies 1311f and the connecting portions 1312f are of a monolithic construction, even if a force such as to peel a certain main body 1311f or a certain connecting portion 1312f from the surface of the second area 13 of the connecting area 11 is applied to the certain main body 1311f, a main body 1311f connected to the certain connecting portion 1312f, or another connecting portion 1312f prevents the certain main body 1311f or the certain connecting portion 1312f from being peeled from the surface of the second area 13 of the connecting area 11. In other words, the main body 1311f or the connecting portion 1312f that is connected to the certain main body 1311f or the certain connecting portion 1312f bears a part of the force such as to peel the certain main body 1311f or the certain connecting portion 1312f from the surface of the second area 13 of the connecting area 11 that is applied to the certain main body 1311f or the certain connecting portion 1312f. Thus, the certain main body 1311f or the certain connecting portion 1312f is made difficult to be peeled from the surface of the second area 13 of the connecting area 11, so that the island-shaped structural members 131f are capable of improving their strength of resistance against peeling from the surface of the second area 13 of the connecting area 11.

It is to be noted that though the sizes Aa, Ab, Ac, Ad, Ae and Af in the second direction of the island-shaped structural members 131a, 131b, 131c, 131d, 131e and 131f are set based on the size Ba in the second direction of the connecting area 11 (i.e., the size in the second direction of the second area 13), they may be set based on a size Ca in the second direction of the sheet-shaped conductive material attached to the second area 13.

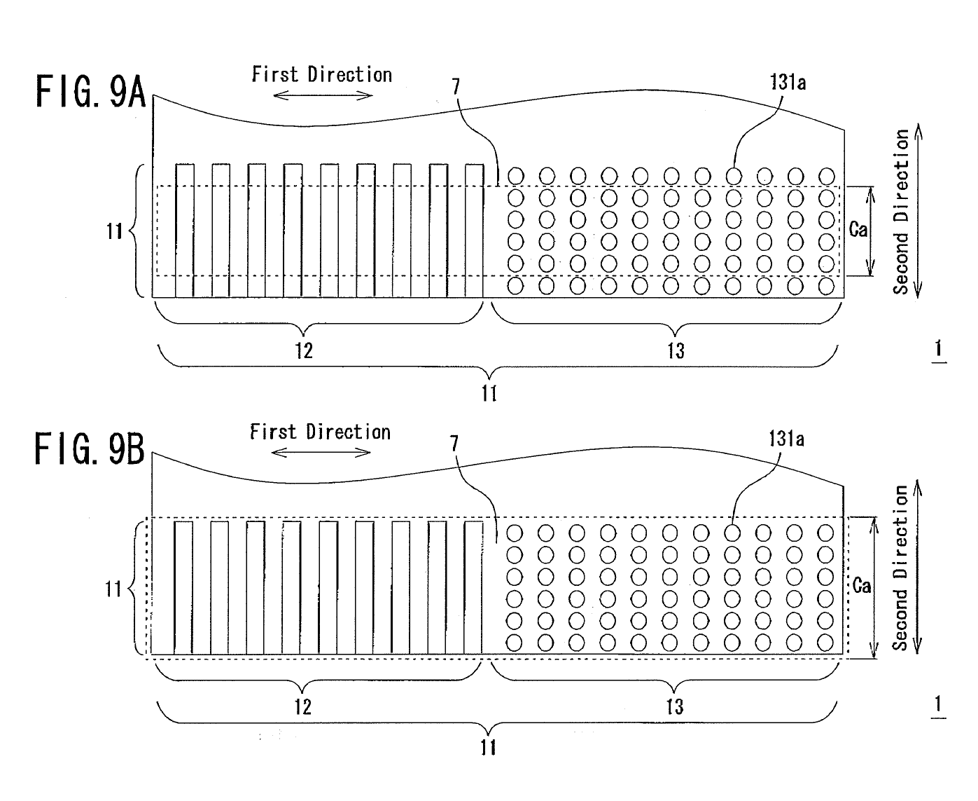

FIGS. 9A and 9B are plan views schematically showing relations between the overall size of a conductive material 7 having a sheet shape that is attached to the connecting area 11 of the circuit board 1 of the preferred embodiment of the present invention and the sizes of the connecting area 11 and the island-shaped structural members 131a, 131b, 131c, 131d, 131e or 131f, where shown in FIG. 9A is the sheet-shaped conductive material 7 attached to the connecting area 11, the sheet-shaped conductive material 7 having the size Ca in the second direction that is smaller than the size in the second direction of the connecting area 11, and shown in FIG. 9B is the sheet-shaped conductive material 7 attached to the connecting area 11, the sheet-shaped conductive material 7 having the size Ca in the second direction that is larger than the size of the connecting area 11.

The sheet-shaped conductive material 7, which is preferably an anisotropic conductive film having a predetermined width, is used to connect the circuit board 1 and the another circuit board. If the size in the second direction of the sheet-shaped conductive material 7 attached to the connecting area 11 is same as or larger than the size in the second direction of the connecting area 11, the sheet-shaped conductive material 7 covers the surface of the second area 13 of the connecting area 11 over the entire length in the second direction.

Having this configuration, the sheet-shaped conductive material 7 covers the entire surface of all of the island-shaped structural members 131a, 131b, 131c, 131d, 131e or 131f on the second area 13 of the connecting area 11. Given portions of the surface of the sheet-shaped conductive material 7 attached to the surface of the second area 13 of the connecting area 11 are in contact with the surfaces of the island-shaped structural members 131a, 131b, 131c, 131d, 131e or 131f. Because the size in the second direction of the sheet-shaped conductive material 7 is same as or larger than the size in the second direction of the second area 13 of the connecting area 11 as described above, there exist portions, which are not in contact with the island-shaped structural members 131a, 131b, 131c, 131d, 131e or 131f, on both sides or one side in the second direction of the given portions of the surfaces of the sheet-shaped conductive material 7 that are in contact with the surfaces of the island-shaped structural members 131a, 131b, 131c, 131d, 131e or 131f. In addition, there exist portions, which are not in contact with the island-shaped structural members 131a, 131b, 131c, 131d, 131e or 131f and are located between them, in an area of the sheet-shaped conductive material 7 where the island-shaped structural members 131a, 131b, 131c, 131d, 131e or 131f are aligned in the second direction. When the sheet-shaped conductive material 7 is attached to the second area 13 of the connecting area 11, the portions of the sheet-shaped conductive material 7 that are not in contact with the island-shaped structural members 131a, 131b, 131c, 131d, 131e or 131f function as pathways through which the air flows in the first direction (i.e., air escape ways) between the sheet-shaped conductive material 7 and the surface of the second area 13 of the connecting area 11.

Meanwhile, when the size Ca in the second direction of the sheet-shaped conductive material 7 is smaller than the size in the second direction of the connecting area 11, a portion of the surface of the second area 13 of the connecting area 11 is exposed without being covered with the sheet-shaped conductive material 7 as shown in FIG. 9A. For this reason, in using the sheet-shaped conductive material 7 having this size, the size of a part or all of the island-shaped structural members 131a, 131b, 131c, 131d, 131e or 131f is set smaller than the size in the second direction of the sheet-shaped conductive material 7. In this configuration, there exist portions, which are not in contact with the island-shaped structural members 131a, 131b, 131c, 131d, 131e or 131f, on both sides or one side in the second direction of the given portions of the surface of the sheet-shaped conductive material 7 that are in contact with the surfaces of the island-shaped structural members 131a, 131b, 131c, 131d, 131e or 131f. In addition, there exist portions, which are not in contact with the island-shaped structural members 131a, 131b, 131c, 131d, 131e or 131f and are located between them, in an area of the sheet-shaped conductive material 7 where the island-shaped structural members 131a, 131b, 131c, 131d, 131e or 131f are aligned in the second direction.

Meanwhile, when the size Ca in the second direction of the sheet-shaped conductive material 7 is larger than the size in the second direction of the connecting area 11, the sheet-shaped conductive material 7 covers the surface of the second area 13 of the connecting area 11 over the entire length in the second direction as shown in FIG. 9B. The surface of the sheet-shaped conductive material 7 having this size is in contact with the island-shaped structural members 131a, 131b, 131c, 131d, 131e or 131f in a similar manner to the sheet-shaped conductive material 7 having the same size in the second direction as the connecting area 11. To be specific, the sheet-shaped conductive material 7 completely covers the island-shaped structural members 131a, 131b, 131c, 131d, 131e or 131f on the second area 13 of the connecting area 11. In this configuration, there exist portions, which are not in contact with the island-shaped structural members 131a, 131b, 131c, 131d, 131e or 131f, on both sides or one side in the second direction of the given portions of the surface of the sheet-shaped conductive material 7 that are in contact with the surfaces of the island-shaped structural members 131a, 131b, 131c, 131d, 131e or 131f.

That is, when the sheet-shaped conductive material 7 having the size larger than the size in the second direction of the connecting area 11 is attached to the second area 13 of the connecting area 11, the size in the second direction of at least some of the island-shaped structural members 131a, 131b, 131c, 131d, 131e or 131f is set smaller than the size in the second direction of the second area 13 of the connecting area 11. Meanwhile, when the sheet-shaped conductive material 7 having the size smaller than the size in the second direction of the connecting area 11 is attached to the second area 13 of the connecting area 11, the size in the second direction of at least some of the island-shaped structural members 131a, 131b, 131c, 131d, 131e or 131f is set smaller than the size in the width direction (the size in the second direction) of the sheet-shaped conductive material 7. That is, the size in the second direction of at least some of the island-shaped structural members 131a, 131b, 131c, 131d, 131e or 131f on the second area 13 of the connecting area 11 is set smaller than either one of the size in the second direction of the second area 13 of the connecting area 11 and the size in the width direction (the size in the second direction) of the sheet-shaped conductive material 7, whichever is smaller.

As described above, it is preferable that the size in the second direction of the island-shaped structural members 131a, 131b, 131c, 131d, 131e or 131f is set based on the size of the sheet-shaped conductive material 7 attached to the second area 13 of the connecting area 11.

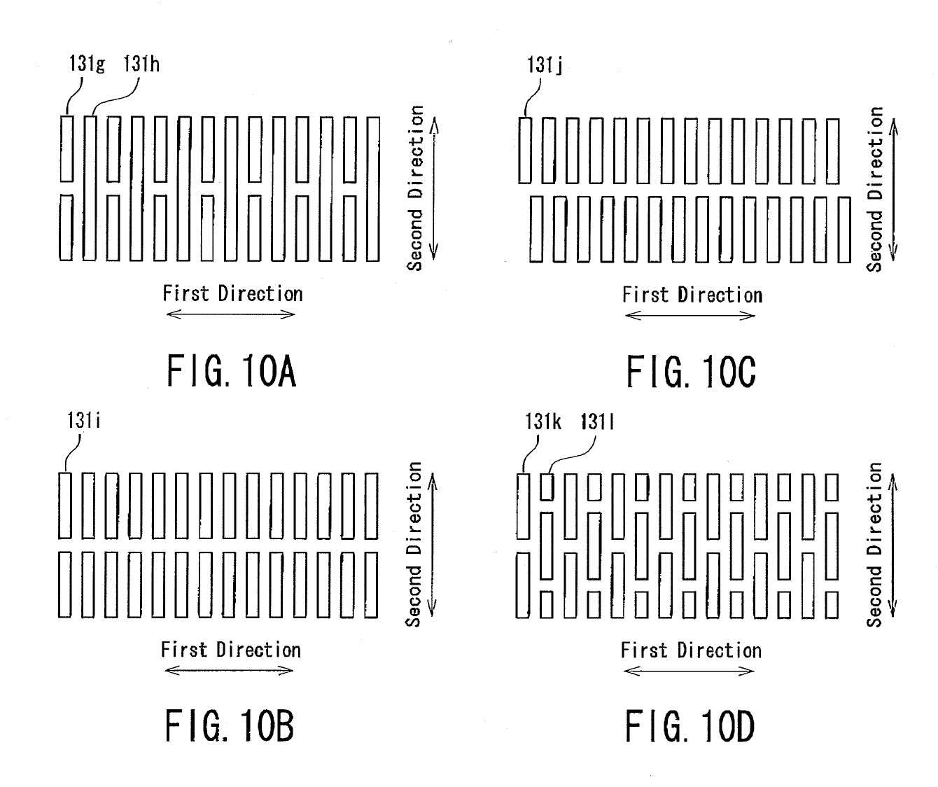

FIGS. 10A, 10B, 10C and 10D, FIGS. 11A, 11B, 11C and 11D, FIGS. 12A, 12B, 12C and 12D, FIGS. 13A, 13B, 13C and 13D, and FIGS. 14A, 14B, 14C and 14D are plan views schematically showing modified configurations of the island-shaped structural members, and modified alignment of the island-shaped structural members. Brief descriptions thereof will be provided.

FIG. 10A is the plan view schematically showing alignment of island-shaped structural members 131g each of which has a quadrilateral shape and island-shaped structural members 131g each of which has a quadrilateral shape. Each of the island-shaped structural members 131g has a rectangular shape, the longer sides of which are substantially parallel to the second direction and the shorter sides of which are substantially parallel to the first direction. The size in the second direction (the length of the longer sides) of the island-shaped structural members 131g is set to be smaller than the size in the second direction of the second area 13 (to be specific, smaller than half the size in the second direction of the second area 13). Each of the island-shaped structural members 131h has a rectangular shape, the longer sides of which are substantially parallel to the second direction and the shorter sides of which are substantially parallel to the first direction. The size in the second direction (the length of the longer sides) of the island-shaped structural members 131h is set to be same as the size in the second direction of the second area 13. Columns in each of which two island-shaped structural members 131g are aligned in the second direction, and the island-shaped structural members 131h are aligned in the first direction while alternately disposed.

FIG. 10B is the plan view schematically showing alignment of island-shaped structural members 131i each of which has a quadrilateral shape. Each of the island-shaped structural members 131i has a rectangular shape, the longer sides of which are substantially parallel to the second direction and the shorter sides of which are substantially parallel to the first direction. The size in the second direction (the length of the longer sides) of the island-shaped structural members 131i is set to be smaller than the size in the second direction of the second area 13 (to be specific, smaller than half the size in the second direction of the second area 13). Columns in each of which two island-shaped structural members 131i are aligned in the second direction are aligned in the first direction. In other words, lines in which the island-shaped structural members 131i are aligned at given intervals in the first direction are aligned in the second direction.

FIG. 10C is the plan view schematically showing alignment of island-shaped structural members 131j each of which has a quadrilateral shape. Each of the island-shaped structural members 131j has a rectangular shape, the longer sides of which are substantially parallel to the second direction and the shorter sides of which are substantially parallel to the first direction. The size in the second direction (the length of the longer sides) of the island-shaped structural members 131j is set to be smaller than the size in the second direction of the second area 13 (to be specific, smaller than half the size in the second direction of the second area 13). Lines in which the island-shaped structural members 131j are aligned in the first direction at given intervals are aligned in the second direction while shifted by half an interval in the first direction. In other words, the island-shaped structural members 131j are aligned in a zigzag arrangement in the first direction.

FIG. 10D is the plan view schematically showing alignment of island-shaped structural members 131k each of which has a quadrilateral shape and island-shaped structural members 131l each of which has a quadrilateral shape. Each of the island-shaped structural members 131k has a rectangular shape, the longer sides of which are substantially parallel to the second direction and the shorter sides of which are substantially parallel to the first direction. The size in the second direction (the length of the longer sides) of the island-shaped structural members 131k is set to be smaller than the size in the second direction of the second area 13 (to be specific, smaller than half the size in the second direction of the second area 13). Each of the island-shaped structural members 131l has a rectangular shape, the longer sides of which are substantially parallel to the second direction and the shorter sides of which are substantially parallel to the first direction. The size in the second direction (the length of the longer sides) of the island-shaped structural members 131h is set to be smaller than the size in the second direction of the second area 13 (to be specific, smaller than a quarter of the size in the second direction of the second area 13). Columns in each of which two island-shaped structural members 131k are aligned in the second direction, Columns in each of which two island-shaped structural members 131l and one island-shaped structural member 131k are aligned in the second direction are aligned in the first direction while alternately disposed. In each column in which two island-shaped structural members 131l and one island-shaped structural member 131k are aligned in the second direction, the one island-shaped structural member 131k is disposed in the middle in the second direction, and the two island-shaped structural members 131l are disposed at both the ends of each column.

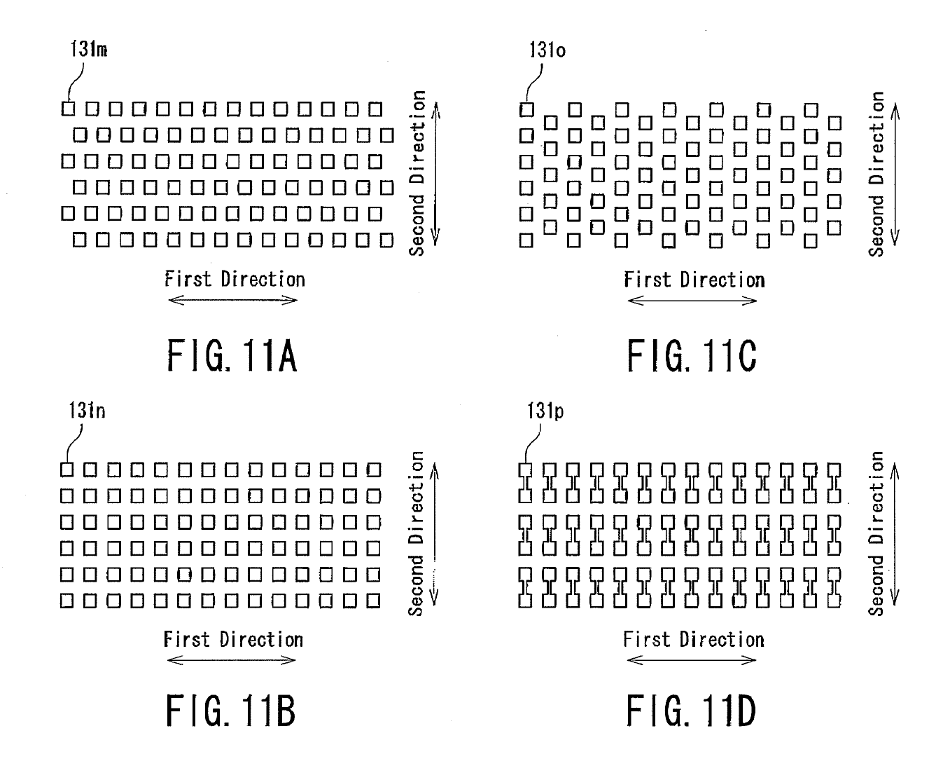

FIG. 11A is the plan view schematically showing alignment of island-shaped structural members 131m each of which has a quadrilateral shape. Each of the island-shaped structural members 131m has a square shape, the sides of which are substantially perpendicular or parallel to the first direction or the second direction. The size in the second direction (the length of the sides) of the island-shaped structural members 131m is set to be smaller than the size in the second direction of the second area 13. Lines in each of which the island-shaped structural members 131m are aligned at given intervals in the first direction are aligned in the second direction. The adjacent lines are shifted by half an interval in the first direction. In other words, columns in which the island-shaped structural members 131m are aligned in a zigzag arrangement in the second direction are aligned in the first direction.

FIG. 11B is the plan view schematically showing alignment of island-shaped structural members 131n each of which has a quadrilateral shape. Each of the island-shaped structural members 131n has a square shape, the sides of which are substantially perpendicular or parallel to the first direction or the second direction. The size in the second direction (the length of the sides) of the island-shaped structural members 131n is set to be smaller than the size in the second direction of the second area 13. The island-shaped structural members 131n are aligned in the first and second directions in a matrix arrangement.

FIG. 11C is the plan view schematically showing alignment of island-shaped structural members 131o each of which has a quadrilateral shape. Each of the island-shaped structural members 131o has a square shape, the sides of which are substantially perpendicular or parallel to the first direction or the second direction. The size in the second direction (the length of the sides) of the island-shaped structural members 131m is set to be smaller than the size in the second direction of the second area 13. Columns in each of which the island-shaped structural members 131o are aligned at given intervals in the second direction are aligned in the first direction. The adjacent columns are shifted by half an interval in the second direction. In other words, lines in which the island-shaped structural members 131o are aligned in a zigzag arrangement in the first direction are aligned in the second direction.

FIG. 11D is the plan view schematically showing alignment of island-shaped structural members 131p each of which includes main bodies and a connecting portion. Each main body of the island-shaped structural members 131p has a square shape, the sides of which are substantially perpendicular or parallel to the first direction or the second direction. The two main bodies of each island-shaped structural member 131p are aligned in the second direction. Each connecting portion has a width that is smaller than the length of a side of each main body. The size in the second direction of the island-shaped structural members 131p is set to be smaller than the size in the second direction of the second area 13. The island-shaped structural members 131p are aligned in the first and second directions in a matrix arrangement.

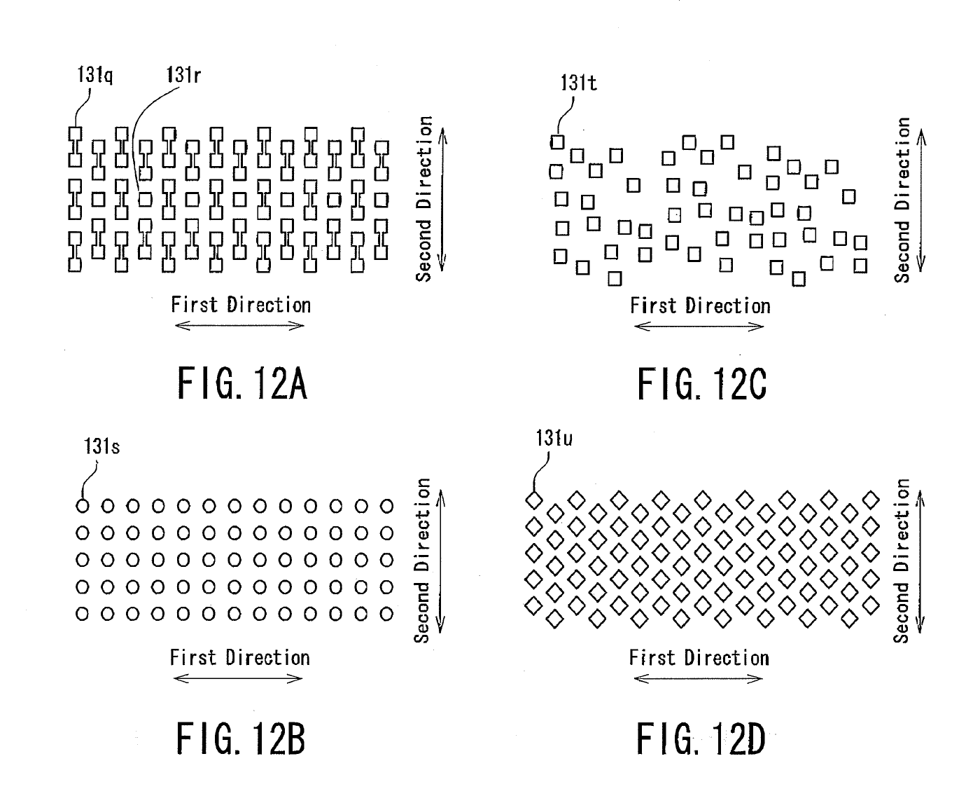

FIG. 12A is the plan view schematically showing alignment of island-shaped structural members 131q each of which includes main bodies and a connecting portion, and island-shaped structural members 131r each of which has a quadrilateral shape. Each main body of the island-shaped structural members 131q has a square shape, the sides of which are substantially perpendicular or parallel to the first direction or the second direction. Each connecting portion has a width that is smaller than the length of a side of each main body. The two main bodies of each island-shaped structural member 131q are aligned in the second direction. The size in the second direction of the island-shaped structural members 131q is set to be smaller than the size in the second direction of the second area 13. Each of the island-shaped structural members 131R has a square shape, the sides of which are substantially perpendicular or parallel to the first direction or the second direction. The size in the second direction (the length of the sides) of the island-shaped structural members 131r is set to be smaller than the size in the second direction of the second area 13. Columns in each of which a given number (three in FIG. 12A) of island-shaped structural members 131q are aligned in the second direction, Columns in each of which a given number (two in FIG. 12A) of island-shaped structural members 131q and a given number (one in FIG. 12A) of island-shaped structural members 131r are aligned in the second direction are aligned in the first direction while alternately disposed. In the columns in each of which the given number of island-shaped structural members 131q and the given number of island-shaped structural members 131r are aligned in the second direction, the given number of island-shaped structural members 131q and the given number of island-shaped structural members 131r are aligned in the second direction while alternately disposed.

FIG. 12B is the plan view schematically showing alignment of island-shaped structural members 131s each of which has a round shape. The size in the second direction (the diameter) of the island-shaped structural members 131s is set to be smaller than the size in the second direction of the second area 13. The island-shaped structural members 131s are aligned in the first and second directions in a matrix arrangement.

FIG. 12C is the plan view schematically showing alignment of island-shaped structural members 131t each of which has a quadrilateral shape. Each of the island-shaped structural members 131t has a square shape, the sides of which are substantially perpendicular or parallel to the first direction or the second direction. The size in the second direction (the length of the sides) of the island-shaped structural members 131t is set to be smaller than the size in the second direction of the second area 13. A given number of island-shaped structural members 131t are aligned in a random arrangement on the second area 13 of the connecting area 11.

FIG. 12D is the plan view schematically showing alignment of island-shaped structural members 131u each of which has a quadrilateral shape. Each of the island-shaped structural members 131u has a square shape, the sides of which are inclined given angles toward the first direction or the second direction. The size in the second direction (the length of the diagonal lines) of the island-shaped structural members 131u is set to be smaller than the size in the second direction of the second area 13. Columns in each of which the island-shaped structural members 131u are aligned at given intervals in the second direction are aligned in the first direction. The adjacent columns are shifted by half an interval in the second direction. In other words, lines in which the island-shaped structural members 131u are aligned in a zigzag arrangement in the first direction are aligned in the second direction.

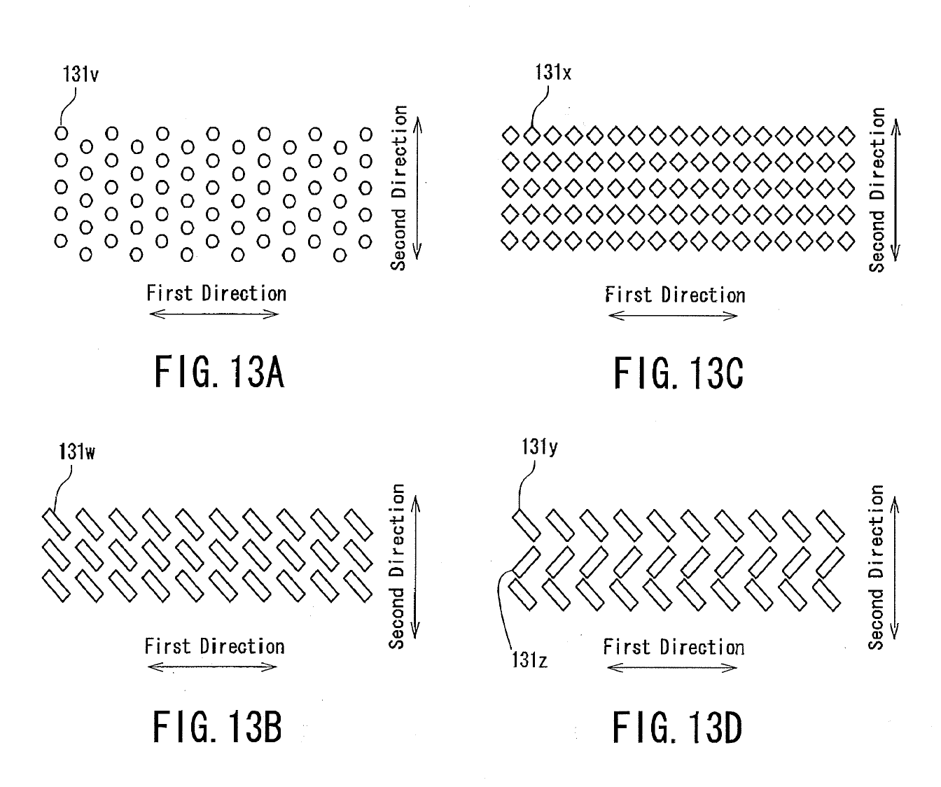

FIG. 13A is the plan view schematically showing alignment of island-shaped structural members 131v each of which has a round shape. The size in the second direction (the diameter) of the island-shaped structural members 131v is set to be smaller than the size in the second direction of the second area 13. Columns in each of which the island-shaped structural members 131v are aligned at given intervals in the second direction are aligned in the first direction. The adjacent columns are shifted by half an interval in the second direction. In other words, lines in which the island-shaped structural members 131v are aligned in a zigzag arrangement in the first direction are aligned in the second direction.

FIG. 13B is the plan view schematically showing alignment of island-shaped structural members 131w each of which has a quadrilateral shape. Each of the island-shaped structural members 131w has a rectangular shape, the sides of which are inclined given angles toward the first direction and the second direction. The size in the second direction of the island-shaped structural members 131w is set to be smaller than the size in the second direction of the second area 13. The island-shaped structural members 131w are aligned in the first and second directions in a matrix arrangement.

FIG. 13C is the plan view schematically showing alignment of island-shaped structural members 131x each of which has a quadrilateral shape. Each of the island-shaped structural members 131x has a square shape, the sides of which are inclined given angles toward the first direction or the second direction. The size in the second direction (the length of the diagonal lines) of the island-shaped structural members 131x is set to be smaller than the size in the second direction of the second area 13. The island-shaped structural members 131x are aligned in the first and second directions in a matrix arrangement.

FIG. 13D is the plan view schematically showing alignment of island-shaped structural members 131y each of which has a quadrilateral shape and island-shaped structural members 131z each of which has a quadrilateral shape. Each of the island-shaped structural members 131y and the island-shaped structural members 131z has a rectangular shape, the sides of which are inclined given angles toward the first direction and the second direction, where the longer sides of the island-shaped structural members 131y are in a direction different from the direction in which the island-shaped structural members 131z are. The size in the second direction of the island-shaped structural members 131y and the island-shaped structural members 131z is set to be smaller than the size in the second direction of the second area 13. Columns in each of which the island-shaped structural members 131y and the island-shaped structural members 131z are aligned in the second direction while alternately disposed are aligned in the first direction. In other words, lines in each of which a given number of island-shaped structural members 131y are aligned at given intervals in the first direction, and lines in each of which a given number of island-shaped structural members 131z are aligned at given intervals in the first direction are aligned in the second direction while alternately disposed.

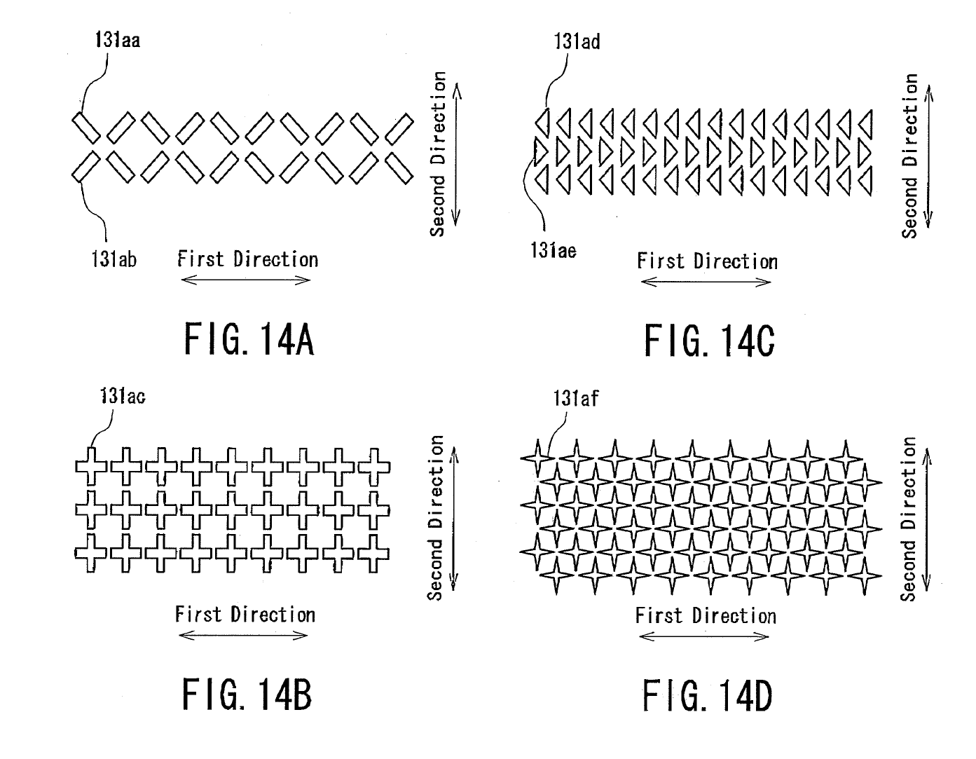

FIG. 14A is the plan view schematically showing alignment of island-shaped structural members 131aa each of which has a quadrilateral shape and island-shaped structural members 131ab each of which has a quadrilateral shape. Each of the island-shaped structural members 131aa and the island-shaped structural members 131ab has a rectangular shape, the sides of which are inclined given angles toward the first direction and the second direction, where the longer sides of the island-shaped structural members 131aa are in a direction different from the direction in which the island-shaped structural members 131ab are. The size in the second direction of the island-shaped structural members 13aa and the island-shaped structural members 131ab is set to be smaller than the size in the second direction of the second area 13. Columns in each of which the island-shaped structural members 131aa and the island-shaped structural members 131ab are aligned in the second direction while alternately disposed are aligned in the first direction. In other words, lines in which the island-shaped structural members 131aa are aligned in the first direction and lines in which the island-shaped structural members 131ab are aligned in the first direction are aligned in the second direction.

FIG. 14B is the plan view schematically showing alignment of island-shaped structural members 131ac each of which has a cross shape. Each of the island-shaped structural members 131ac has a shape such that a rectangle having their longer sides substantially parallel to the first direction and a rectangle having their longer sides substantially parallel to the second direction overlap each other. The size in the second direction of the island-shaped structural members 131ac is set to be smaller than the size in the second direction of the second area 13. A given number of island-shaped structural members 131ac are aligned in the first and second directions in a matrix arrangement.

FIG. 14C is the plan view schematically showing alignment of island-shaped structural members 131ad each of which has a triangular shape and island-shaped structural members 131ae each of which has a triangular shape. The island-shaped structural members 131ad and the island-shaped structural members 131ae has the identical shape, but the island-shaped structural members 131ad and the island-shaped structural members 131ae are oriented in different directions. Columns in each of which the island-shaped structural members 131ad and the island-shaped structural members 131ae are aligned in the second direction while alternately disposed are aligned in the first direction. In other words, lines in which the island-shaped structural members 131ad are aligned at given intervals in the first direction and lines in which the island-shaped structural members 131ad are aligned at given intervals in the first direction are aligned in the second direction while alternately disposed.

FIG. 14D is the plan view schematically showing alignment of island-shaped structural members 131af each of which has a cross shape. Each of the island-shaped structural members 131af has a shape such that two rhombuses (a rhombus that is longer in the first direction and a rhombus that is longer in the second direction) overlap each other. In other words, each of the island-shaped structural members 131af has a shape such that four tapered arms jut out of the center. Columns in each of which the island-shaped structural members 131af are aligned at given intervals in the second direction are aligned in the first direction. The adjacent columns are shifted by half an interval in the second direction.

As described above, the island-shaped structural members 131a to 131af having various shapes can be used. In addition, the island-shaped structural members 131a to 131af can be aligned in various arrangements.

The island-shaped structural members 131a to 131af are made from a conductor film same as the electrode terminals 121 provided on the first area 12 of the connecting area 11, or made from a photoresist material, or an ink made of a resin material.

The island-shaped structural members 131a to 131af are formed in the following manner.

When the island-shaped structural members 131a to 131af are made from the same conductor film as the electrode terminals 121 provided on the first area 12 of the connecting area 11, the island-shaped structural members 131a to 131af are formed in the same process in which the electrode terminals 121 are formed. To be specific, the conductor film is formed on the unfinished circuit board 1 by etching, whereby the electrode terminals 121 are formed on the first area 12 of the connecting area 11 and the island-shaped structural members 131a to 131af are formed on the second area 13 of the connecting area 11.

The size, shape and alignment of the island-shaped structural members 131a to 131af to be formed are determined based on the size, shape and alignment of an etching mask that is formed on the conductor film when the conductor film is formed by etching. To be specific, the portion of the conductor film that is covered with the etching mask is left while the portion of the conductor film that is not covered with the etching mask (i.e., the exposed portion) is removed. The left portion becomes the island-shaped structural members 131a to 131af. Thus, by setting the size and shape of the etching mask as appropriate, the size, shape and the alignment of the island-shaped structural members 131a to 131af are determined as appropriate.

When the island-shaped structural members 131a to 131af are made from a photoresist material, a photolithographic method is used. To be specific, a layer of the photoresist material is first formed on the circuit board 1 (at least on the second area 13 of the connecting area 11). Then, the formed photoresist material layer is subjected to an exposure process with the use of a photo mask on which a given light-transmitting pattern and a given light-shielding pattern are formed. Then, the photoresist material layer subjected to the exposure process is subjected to a processing procedure, whereby an unnecessary portion of the photoresist material is removed therefrom. Thus the island-shaped structural members 131a to 131af made from the photoresist material are formed on the second area 13 of the connecting area 11 of the circuit board 1. The kind of photoresist material is not limited specifically. Various known photoresist materials such as an acrylate resin photoresist material can be used.

The size, shape and alignment of the island-shaped structural members 131a to 131af to be formed are determined based on the size, shape and alignment of the light-transmitting pattern and the light-shielding pattern of the photo mask. For example, if a positive photoresist material is used, the portion of the photoresist material that is irradiated with light through the light-transmitting pattern of the photo mask is removed, and the portion of the photo resist material that is shielded from light by the light-shielding pattern of the photo mask is left on the second area 13 of the connecting area 11 of the circuit board 1. If a negative photoresist material is used, the portion of the photoresist material that is shielded from light by the light-shielding pattern of the photo mask is removed, and the portion of the photoresist material that is irradiated with light through the light-transmitting pattern of the photo mask is left on the second area 13 of the connecting area 11 of the circuit board 1. The left portion becomes the island-shaped structural members 131a to 131af. Thus, by setting the size and shape of the light-transmitting pattern and the light-shielding pattern of the photo mask as appropriate, the size, shape and the alignment of the island-shaped structural members 131a to 131af are determined as appropriate.

When the island-shaped structural members 131a to 131af are made from an ink made of a resin material, a method is used in which the ink is placed on the second area 13 of the connecting area 11 of the circuit board 1 by silkscreening. The ink that is placed and cured becomes the island-shaped structural members 131a to 131af.

The size, shape and alignment of the island-shaped structural members 131a to 131af to be formed are determined based on the size, shape and alignment of “holes” formed on a screen used in the silkscreening. To be specific, the ink that passes through the screen becomes the island-shaped structural members 131a to 131af, the ink having a size and shape equal to those of the “holes” are formed. Thus, by setting the size and shape of “holes” formed on the screen as appropriate, the size, shape and the alignment of the island-shaped structural members 131a to 131af are determined as appropriate.

Next, a description of a connecting method and a connecting structure between the circuit board 1 of the preferred preferred embodiment of the present invention and another circuit board will be provided.

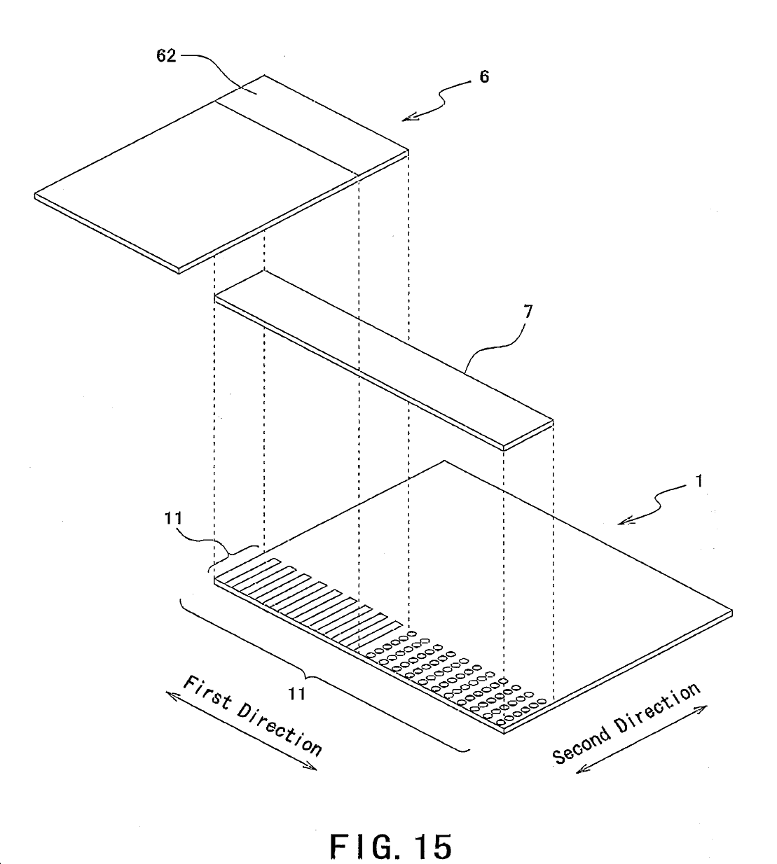

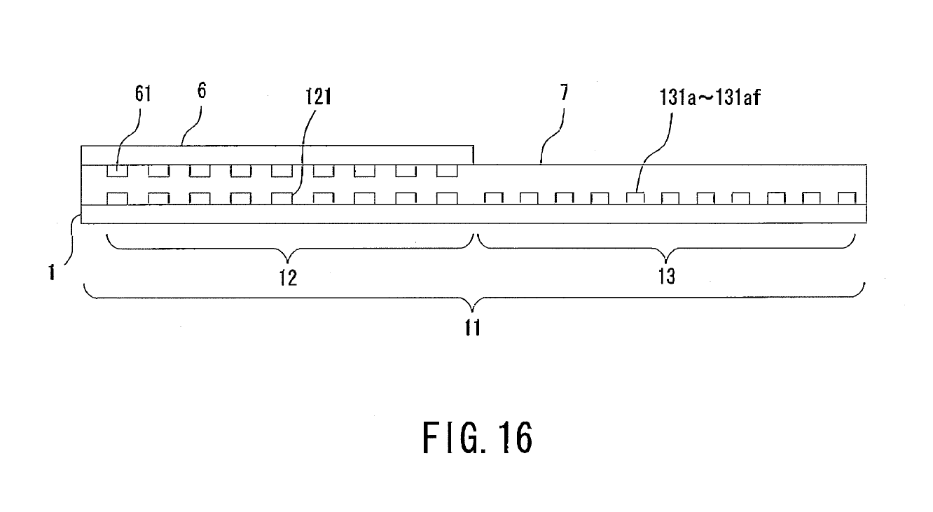

FIG. 15 is an exploded perspective view schematically showing the connecting method and the connecting structure between the circuit board 1 of the preferred embodiment of the present invention and the another circuit board 6, where the circuit boards are yet to be connected. FIG. 16 is a cross-sectional view schematically showing the connecting structure between the circuit board 1 of the preferred embodiment of the present invention and the another circuit board 6, where the circuit boards are connected.

As shown in FIGS. 15 and 16, the sheet-shaped conductive material 7 such as an anisotropic conductive film is used for connecting the circuit board 1 to the another circuit board 6. The sheet-shaped conductive material 7 has a given thickness and the shape of a long strip. Both sides in a thickness direction of the sheet-shaped conductive material 7 are made adhesive. A separator (protection sheet) is attached to one side in the thickness direction of the sheet-shaped conductive material 7 (not shown).

The width of the sheet-shaped conductive material 7 is same or larger than the size in the second direction of the second area 13 of the connecting area 11 of the circuit board 1. However, when the size in the second direction of at least a part of the island-shaped structural members 131a to 131af provided on the second area 13 of the connecting area 11 of the circuit board 1 is smaller than the width of the sheet-shaped conductive material 7, the width of the sheet-shaped conductive material 7 may be smaller than the size in the second direction of the second area 13 of the connecting area 11.

The another circuit board 6 includes a connecting area 62. A given number of electrode terminals are provided on the connecting area 62 (not shown in FIG. 15). Electrode terminals having a configuration same as the electrode terminals 121 provided on the first area 12 of the connecting area 11 of the circuit board 1 are used as the electrode terminals provided on the another circuit board 6.

First, the sheet-shaped conductive material 7 is attached to the connecting area 11 of the circuit board 1. To be specific, the sheet-shaped conductive material 7 is attached thereto with its longer direction parallel to the first direction and with its width direction parallel to the second direction. When the width of the sheet-shaped conductive material 7 is same or larger than the size in the second direction of the connecting area 11 of the circuit board 1, the sheet-shaped conductive material 7 covers the surface of the second area 13 of the connecting area 11 over the entire length in the second direction. Because the separator is attached to the one side in the thickness direction of the sheet-shaped conductive material 7, the other side of the sheet-shaped conductive material 7 to which no separator is attached is attached to the surface of the connecting area 11 of the circuit board 1 while the separator is still attached to the one side.

The circuit board 1 of the preferred embodiment of the present invention allows the sheet-shaped conductive material 7 to be tightly connected to the surface of the second area 13 of the connecting area 11 for the following reasons.

When the sheet-shaped conductive material 7 is attached to the surface of the second area 13 of the connecting area 11, the surface of the sheet-shaped conductive material 7 is firstly brought into contact with the surfaces of the island-shaped structural members 131a to 131af, which form convex portions, and then gets into the spaces between the island-shaped structural members 131a to 131af, the spaces forming concave portions. To be specific, during the time from when the surface of the sheet-shaped conductive material 7 is brought into contact with the surfaces of the island-shaped structural members 131a to 131af until the surface of the sheet-shaped conductive material 7 gets into the spaces between the island-shaped structural members 131a to 131af, there exists a clearance between the sheet-shaped conductive material 7 and the concave portions, through which air flows.

Some of the island-shaped structural members 131a to 131af provided on the second area 13 of the connecting area 11 have the sizes in the second direction that are smaller than the size in the second direction of the connecting area 11. Thus, there exist clearances on both sides or one side in the second direction of the island-shaped structural members 131a to 131af (also there exist clearances in the spaces between the island-shaped structural members 131a to 131af when the island-shaped structural members 131a to 131af having the smaller sizes as described above are included and aligned in the second direction) just after the sheet-shaped conductive material 7 is brought into contact with the surfaces of the island-shaped structural members 131a to 131af, so that the air can move in the first direction through the clearances.

Thus, when the sheet-shaped conductive material 7 is attached to the surface of the second area 13 of the connecting area 11, the air existing between the surface of the second area 13 of the connecting area 11 and the sheet-shaped conductive material 7 can be made to escape not only in the first direction but also in the second direction, which can prevent air bubbles from being produced between the sheet-shaped conductive material 7 and the surface of the second area 13 of the connecting area 11. Because air bubbles are not produced between the sheet-shaped conductive material 7 and the surface of the second area 13 of the connecting area 11, the sheet-shaped conductive material 7 can be brought into intimate contact over the entire length with the surface of the second area 13 of the connecting area 11. Thus, a contact area between the surface of the second area 13 of the connecting area 11 and the sheet-shaped conductive material 7 can be prevented from decreasing. Strength in connection between the surface of the second area 13 of the connecting area 11 and the sheet-shaped conductive material 7 can be prevented from decreasing.

Especially when the sheet-shaped conductive material 7 is attached gradually in the first direction to the surface of the second area 13 of the connecting area 11, the sheet-shaped conductive material 7 can be attached thereto while the air can be made to escape in the first direction.

When the width of the sheet-shaped conductive material 7 is smaller than the size in the width direction of the second area 13 of the connecting area 11, a portion of the surface of the second area 13 of the connecting area 11 is not covered with the sheet-shaped conductive material 7. Even if the portion is not covered, when some of the island-shaped structural members 131a to 131af provided on the second area 13 of the connecting area 11 of the circuit board 1 have the sizes in the second direction that are smaller than the width of the sheet-shaped conductive material 7, the same action and effect as those obtained by the above-described configuration can be obtained for the same reason described above.

Then, after the sheet-shaped conductive material 7 is attached over the entire length to the connecting area 11, the separator is peeled off. When the separator is peeled off, a force such as to peel the sheet-shaped conductive material 7 from the surface of the connecting area 11 could be applied to the sheet-shaped conductive material 7. However, because the given number of island-shaped structural members 131a to 131af form the surface asperities on the second area 13 of the connecting area 11, the sheet-shaped conductive material 7 is brought into intimate contact with the surface asperities (gets into the concave portions). Thus, producing an anchor effect, the sheet-shaped conductive material 7 can be connected tightly to the surface of the second area 13 of the connecting area 11. In addition, air bubbles are not produced between the sheet-shaped conductive material 7 and the surface of the second area 13 of the connecting area 11, so that the sheet-shaped conductive material 7 is brought into intimate contact with the surface of the second area 13 of the connecting area 11. Thus, in the process of peeling the separator from the sheet-shaped conductive material 7, the sheet-shaped conductive material 7 is prevented from being peeled from the surface of the connecting area 11.

Even if the size in the second direction (width) of the sheet-shaped conductive material 7 is smaller than the size in the second direction of the second area 13 of the connecting area 11, the same action and effect as those obtained by the above-described configuration can be also obtained because the island-shaped structural members 131a to 131af having the sizes smaller than the size in the second direction of the sheet-shaped conductive material 7 are provided on the second area 13 of the connecting area 11.

Then, after positional adjustment, the connecting area 62 of the another circuit board 6 is attached to the first area 12 of the connecting area 11 (i.e., the surface of the sheet-shaped conductive material 7 attached to the surface of the connecting area 12, which is on the side from which the separator is peeled off). To be specific, the positional adjustment is made such that the electrode terminals 121 provided on the connecting area 11 of the circuit board 1 are opposed, sandwiching the sheet-shaped conductive material 7, to corresponding electrode terminals 61 provided on the connecting area 62 of the another circuit board 6.

Then, the first area 12 of the connecting area 11 of the circuit board 1 and the connecting area 62 of the another circuit board 6 are pre-bonded. For example, heat and pressure are applied to the sheet-shaped conductive material 7 with the use of a pre-bonding machine to the extent that the sheet-shaped conductive material 7 is not cured. Thus, the connecting area 11 of the circuit board 1 and the connecting area 62 of the another circuit board 6 are pre-bonded.

Then, the connecting area 11 of the circuit board 1 and the connecting area 62 of the another circuit board 6 that have been pre-bonded are post-bonded. In the post-bonding, heat and pressure are applied to the sheet-shaped conductive material 7 with the use of a bonding machine. By the post-bonding, the electrode terminals opposed to each other sandwiching the sheet-shaped conductive material 7 (the electrode terminals 121 provided on the first area 12 of the connecting area 11 of the circuit board 1 and the electrode terminals 61 provided on the connecting area 62 of the another circuit board 6) are electrically connected as shown in FIG. 16. Further, the sheet-shaped conductive material 7 is cured, which achieves strength in physical connection between the first area 12 of the connecting area 11 of the circuit board 1 and the connecting area 62 of the another circuit board 6.

In the pre-bonding process and the post-bonding process, the sheet-shaped conductive material 7 is heated. If there exist air bubbles between the second area 13 of the connecting area 11 and the sheet-shaped conductive material 7, the pressure inside the air bubbles increases due to increase in temperature when the sheet-shaped conductive material 7 is heated in the pre-bonding process and the post-bonding process. Thus, the air bubbles could remain without bursting even under pressure. The sheet-shaped conductive material 7 is off the surface of the second area 13 of the connecting area 11 of the circuit board 1 at the portions where the air bubbles exist, and thus the strength in connection between them is decreased.

However, because the circuit board 1 can prevent air bubbles from being produced between the sheet-shaped conductive material 7 and the surface of the second area 13 of the connecting area 11, decrease in connection strength between the sheet-shaped conductive material 7 and the surface of the second area 13 of the connecting area 11 resulting from existence of air bubbles is not caused.

Next, a description of a display panel assembly 8 of one of preferred embodiments of the present invention will be provided.

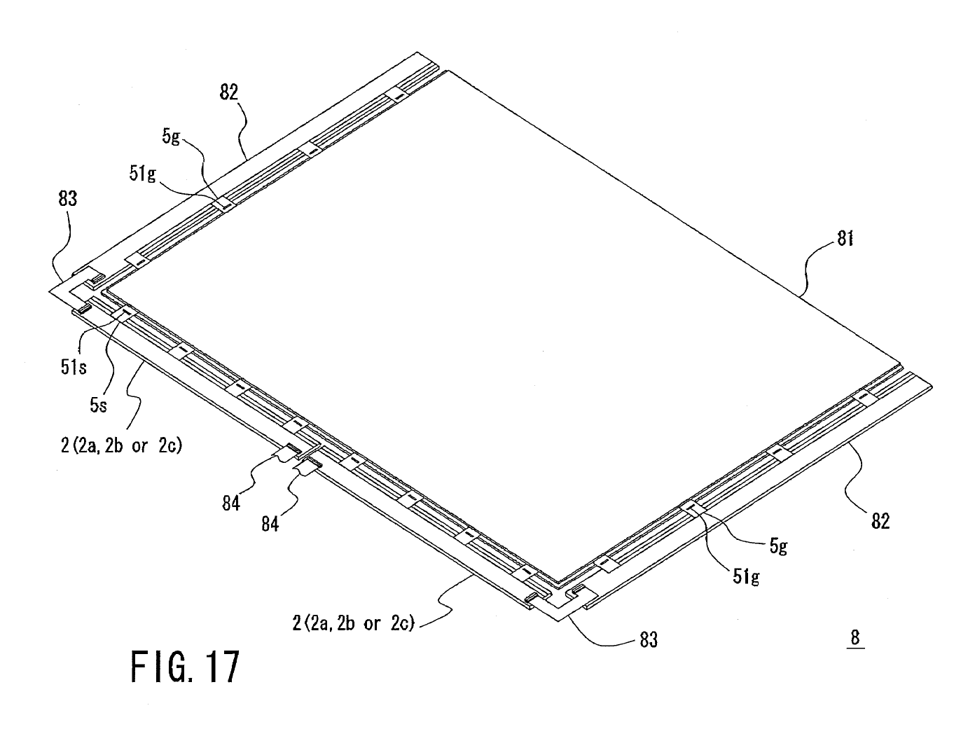

FIG. 17 is an external perspective view schematically showing a configuration of the display panel assembly 8 of the preferred embodiment of the present invention. As shown in FIG. 17, the display panel assembly 8 of the preferred embodiment of the present invention includes a display panel 81, a given number of first circuit boards 5s and 5g, and a given number of second circuit boards 2 and 82. The first circuit boards 5s and 5g are connected to the display panel 81 at predetermined positions on the display panel 81, and connected to the second circuit boards 2 and 82.

An active matrix type liquid crystal display panel is used as the display panel 81 of the display panel assembly 8. A brief description of a configuration of the active matrix type liquid crystal display panel is provided. A general active matrix type liquid crystal display panel includes a TFT array substrate and a common substrate. A color filter is usually used as the common substrate. The TFT array substrate and the common substrate are bonded together having a given tiny space therebetween with the use of a sealing material. Liquid crystals are filled between the TFT array substrate and the common substrate. The filled liquid crystals are sealed with the sealing material.

The TFT array substrate includes an active area and a peripheral area of a panel. The active area is referred to also as a “display area” or a “pixel area”.

A given number of pixel electrodes are provided in a given arrangement, and switching elements arranged to drive the pixel electrodes are provided in a given arrangement in the active area. For example, the pixel electrodes and the switching elements are provided in a matrix arrangement. TFTs (Thin Film Transistors) including gate electrodes, source electrodes and drain electrodes are used as the switching elements. A given number of source lines arranged to send given signals to the source electrodes of the switching elements, and a given number of gate lines arranged to send given signals to the gate electrodes of the switching elements are also provided in the active area. The drain electrodes of the switching elements are electrically connected to the corresponding pixel electrodes. In addition, reference lines arranged to provide the pixel electrodes with storage capacitors are sometimes provided.

It is to be noted that the source lines are referred to also as “data lines” or “source bus lines”, and the gate lines are referred to also as “scanning lines” or “gate bus lines”. The reference lines are referred to also as “storage capacitor lines”, “auxiliary capacitance lines”, “Cs lines”, “storage capacitor bus lines”, “storage capacitor bus lines” and “Cs bus lines”.

The peripheral area of the panel defines an area having a frame shape, which has a given width, and is disposed around the periphery of the active area. Connecting areas are provided on a given side of the periphery of the peripheral area of the panel. To be specific, when the display panel has a quadrilateral shape, the connecting areas are provided on two adjacent sides (one longer side and one shorter side) or three given sides (one longer side and both the shorter sides) among the four sides of the periphery of the peripheral area of the panel (the periphery of the TFT array substrate). In FIG. 17, the display panel 81 of the display panel assembly 8 has a configuration such that the connecting areas are provided on one longer side and both the shorter sides.

A given number of first areas are provided at given intervals in the connecting areas of the TFT array substrate. A given number of electrode terminal for wiring are provided on each first area. The first areas of the connecting areas of the TFT array substrate have a configuration almost same as the first area 12 of the connecting area 11 of the circuit board 1. Lines arranged to connect the electrode terminals for wiring and the corresponding source lines, and lines arranged to connect the electrode terminals for wiring and the corresponding gate lines are provided in the peripheral area of the panel. To be specific, the electrode terminals for wiring provided on the first areas of the peripheral area of the panel on the longer side of the TFT array substrate are connected to the corresponding source lines provided on the active area. The electrode terminals for wiring provided on the first areas of the peripheral area of the panel on the shorter sides of the TFT array substrate are connected to the corresponding gate electrodes provided on the active area.

The first circuit boards 5s are circuit boards each incorporating driver ICs or driver Sis (hereinafter, referred to as “source drivers 51s”) arranged to generate signals sent to the source electrodes of the switching elements, and the first circuit boards 5g are circuit boards each incorporating driver ICs or driver Sis (hereinafter, referred to as “gate drivers 51g”) arranged to generate signals sent to the gate electrodes of the switching elements.

Flexible circuit boards produced by a TAB (Tape Automated Bonding) technique are used as the first circuit boards 5s incorporating the source drivers 51s, and the first circuit boards 5g incorporating the gate drivers 51g. Examples of the flexible circuit boards include a TCP (Tape Carrier Package) and a COF (Chip On Film).

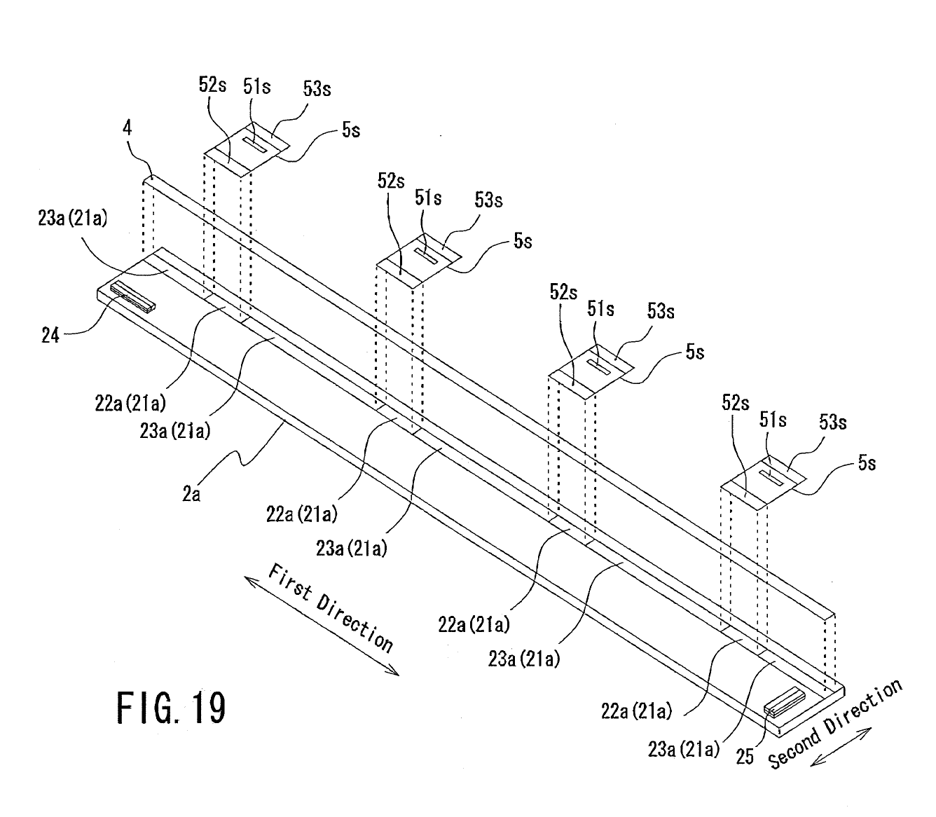

The first circuit boards 5s incorporating the source drivers 51s have a quadrilateral shape (as shown in FIG. 19). An input connecting area 52s is provided on one side among the four sides of each first circuit board 5s. An output connecting area 53s is provided on one side of each first circuit board 5s that is opposed to the side where the input connecting area 52 is provided. A given number of input electrode terminals are provided on each input connecting area 52s. A given number of output electrode terminals are provided on each output connecting area 53s. The first circuit boards 5s incorporating the source drivers 51s include lines arranged to send signals inputted from the input electrode terminals to the source drivers 51s, and lines arranged to send signals produced by the source drivers 51s to the output electrode terminals. The first circuit boards 5g incorporating the gate drivers 51g have a configuration same as the first circuit boards 5s incorporating the source drivers 51s. The “source drivers 51s” should be read as the “gate drivers 51g” in the description above.

The source drivers 51s are arranged to generate given signals to be sent to the source electrodes of the switching elements based on given signals inputted from the outside (the given signals are referred to also as “control signals”). The signals the source drivers 51s generate are for setting gray scales (luminance) of the pixel electrodes, which are sometimes referred to as “gray scale signals” and “image signals”. The gate drivers 51g are arranged to generate given signals sent to the gate electrodes of the switching elements of the display panel 81 based on given signals inputted from the outside (the given signals are referred to also as “control signals”). The signals the gate drivers 51g generate are for ON/OFF controlling the corresponding switching elements, which are sometimes referred to as “gate pulses” and “selection pulses”.

The second circuit boards 2 are connected to the first circuit boards 5s incorporating the source drivers 51s. The second circuit boards 82 are connected to the first circuit boards 5g incorporating the gate drivers 51g. Hereinafter, the second circuit boards 2 connected to the first circuit boards 5s incorporating the source drivers 51s are referred to as the “source-side second circuit boards 2”, and the second circuit boards 82 connected to the first circuit boards 5g incorporating the gate drivers 51g are referred to as the “gate-side second circuit boards 82”

Source-side second circuit boards 2a of a first preferred embodiment of the present invention, source-side second circuit boards 2b of a second preferred embodiment of the present invention, or source-side second circuit boards 2c of a third preferred embodiment of the present invention that are to be described below are used as the source-side second circuit boards 2. The source-side second circuit boards, which are indicated with the reference numeral “2”, define the source-side second circuit boards 2a of the first preferred embodiment of the present invention, the source-side second circuit boards 2b of the second preferred embodiment of the present invention, or the source-side second circuit boards 2c of the third preferred embodiment of the present invention.

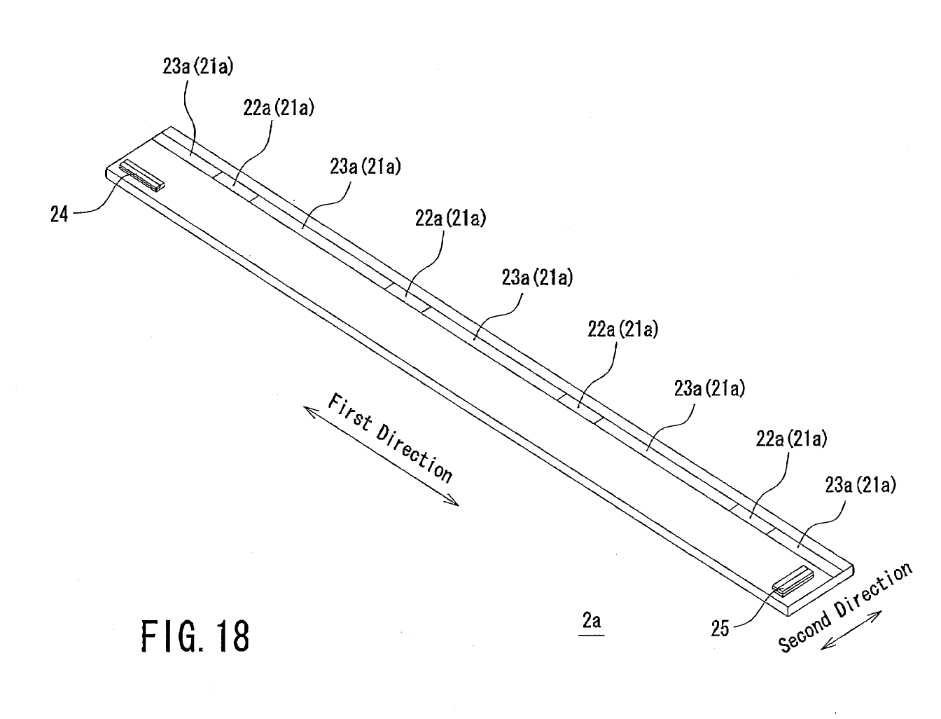

FIG. 18 is an external perspective view schematically showing a configuration of the source-side second circuit board 2a of the first preferred embodiment of the present invention.

The source-side second circuit board 2a has a long quadrilateral shape. The longer direction of the source-side second circuit board 2a is referred to as a first direction, and the direction perpendicular to the longer direction is referred to as a second direction. A connecting area 21a having a given width (size in the second direction) is provided over the entire length in the first direction on the source-side second circuit board 2a. An input connector 24 arranged to input given signals from the outside is provided in the vicinity of one end in the first direction of the source-side second circuit board 2a. An output connector 25 arranged to output given signals to the outside (to a gate-side second circuit board 82) is provided in the vicinity of the other end in the first direction of the source-side second circuit board 2a.

The connecting area 21a includes a given number of first areas 22a and a given number of second areas 23a. To be specific, the given number of first areas 22a (the same number as the first circuit boards 5s incorporating the source drivers 51s to be connected to: four in FIG. 18) are aligned at given intervals in the first direction. The second areas 23a are disposed between the first areas 22a and outside of the two first areas 22a at both the ends in the first direction of the source-side second circuit board 2a. In other words, the second areas 23a are disposed at both the ends in the first direction of the source-side second circuit board 2a, between which the first areas 22a and the second areas 23a are aligned alternately in the first direction.

The connecting area 21a defines an area on which a sheet-shaped conductive material 4 that has the shape of a long strip is attached. An anisotropic conductive film having a given width is used as the sheet-shaped conductive material. Both sides in a thickness direction of the anisotropic conductive film are made adhesive. A separator (protection sheet) is attached to one side in the thickness direction of the anisotropic conductive film before use.

The first areas 22a define areas to which the first circuit boards 5s incorporating the source drivers 51s are attached with the use of the sheet-shaped conductive material 4. A given number of electrode terminals (not shown) are aligned at given intervals in the first direction on each first area 22a. The first areas 22a have a configuration same as the first area 12 of the connecting area 11 of the circuit board 1, so that a detailed description thereof is omitted (see FIG. 1 and FIGS. 2A and 2B).

The second areas 23a define areas to which the sheet-shaped conductive material 4 is attached. Island-shaped structural members having a given size and a given shape (not shown) are aligned in a given arrangement in each second area 23a. The second areas 23a have a configuration (size, shape and alignment) same as the second area 13 of the connecting area 11 of the circuit board 1, so that a detailed description thereof is omitted (see FIG. 1 to FIG. 8B, FIGS. 10A to 14D).

In addition to the constituent elements described above, the source-side second circuit board 2a of the first preferred embodiment of the present invention includes lines arranged to send the signals from the outside to the electrode terminals on the first areas 22a of the connecting area 21a, and lines arranged to send the signals from the outside to the output connector 25. The signals inputted from the input connector 24 are distributed to the corresponding electrode terminals on the first areas 22a of the connecting area 21a via those lines. In addition, the signals inputted from the input connector 24 are distributed to the output connector 25 via those lines.

A description of a connecting method and a connecting structure between the source-side second circuit board 2a of the first preferred embodiment of the present invention and the first circuit boards 5s incorporating the source drivers 51s will be provided.

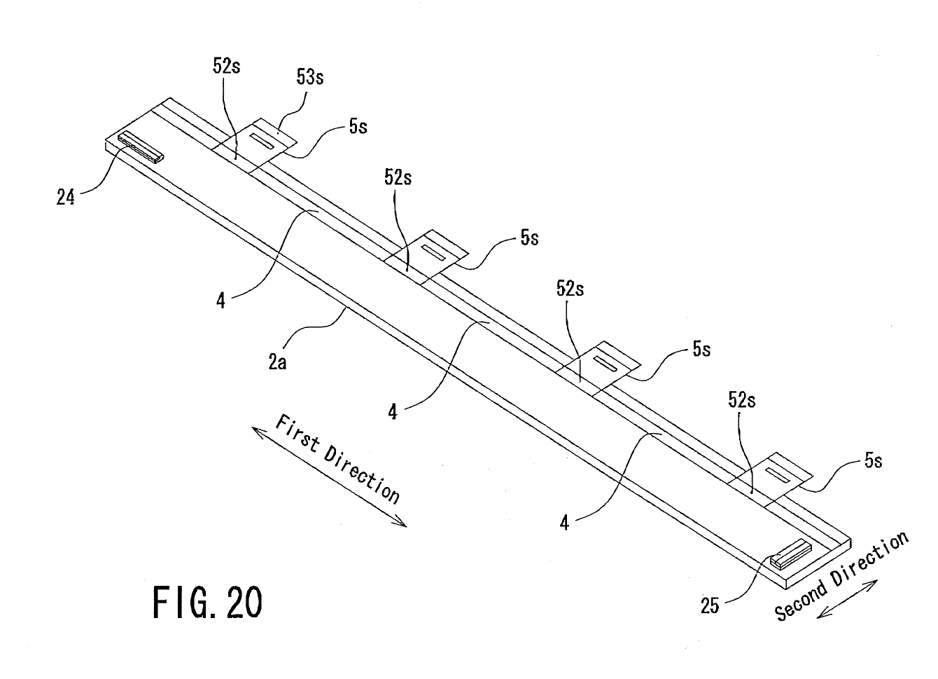

FIG. 19 is an exploded perspective view schematically showing the connecting method and the connecting structure between the source-side second circuit board 2a of the first preferred embodiment of the present invention and the first circuit boards 5s incorporating the source drivers 51s, where the source-side second circuit board 2a and the first circuit boards 5s are yet to be connected. FIG. 20 is an exploded perspective view schematically showing the connecting method and the connecting structure between the source-side second circuit board 2a of the first preferred embodiment of the present invention and the first circuit boards 5s incorporating the source drivers 51s, where the source-side second circuit board 2a and the first circuit boards 5s are connected.

The sheet-shaped conductive material 4, which is preferably an anisotropic conductive film, is used to connect the source-side second circuit board 2a and the first circuit boards 5s. The sheet-shaped conductive material 4 has a width same as or larger than the size in the second direction of the connecting area 21a. However, if a condition is satisfied that at least some of the island-shaped structural members have sizes in the second direction that are smaller than the width of the sheet-shaped conductive material 4, the width of the sheet-shaped conductive material 4 may be smaller than the size in the second direction of the connecting area 21a.

First, one sheet of the sheet-shaped conductive material 4 is attached over the entire length to the connecting area 21a of the source-side second circuit board 2a as shown in FIG. 19. To be specific, one sheet of the sheet-shaped conductive material 4 is attached thereto with its longer direction parallel to the first direction and with its width direction parallel to the second direction.

The second areas 23a of the connecting area 21a of the source-side second circuit board 2a of the first preferred embodiment of the present invention have the configuration same as the second area 13 of the connecting area 11 of the circuit board 1, which prevents air bubbles from being produced between the second areas 23a of the connecting area 21a and the sheet-shaped conductive material 4 for the same reason as the circuit board 1. Thus, the sheet-shaped conductive material 4 can be brought into intimate contact with the surface of the second areas 23a of the connecting area 21a. In addition, producing an anchor effect, the sheet-shaped conductive material 4 can be connected tightly to the surface of the second areas 23a of the connecting area 21a.

When the sheet-shaped conductive material 4 is attached gradually in the first direction to the one end to the other end of the connecting area 21a, the attachment can be achieved while the air between the second areas 23a of the connecting area 21a and the sheet-shaped conductive material 4 can be made to escape not only in the second direction but also in the first direction, which more effectively prevents air bubbles from being produced between the second areas 23a of the connecting area 21a and the sheet-shaped conductive material 4.

Then, after the sheet-shaped conductive material 4 is attached over the entire length to the connecting area 21a, the separator is peeled off. When the separator is peeled off, a force such as to peel the sheet-shaped conductive material 4 from the surface of the connecting area 21a could be applied to the sheet-shaped conductive material 4. However, because the given number of island-shaped structural members form the surface asperities on the second areas 23a of the connecting area 21a, the sheet-shaped conductive material 4 is brought into intimate contact with the surface asperities (gets into the concave portions). Thus, producing an anchor effect, the sheet-shaped conductive material 4 can be connected tightly to the surface of the second areas 23a of the connecting area 21a. In addition, as described above, air bubbles are not produced between the sheet-shaped conductive material 4 and the surface of the second areas 23a of the connecting area 21a, so that the sheet-shaped conductive material 4 is brought into intimate contact with the surface of the second areas 23a of the connecting area 21a leaving no space therebetween, which causes no decrease in connection strength resulting from existence of air bubbles. Thus, in the process of peeling the separator from the sheet-shaped conductive material 4, the sheet-shaped conductive material 4 is prevented from being peeled from the surface of the connecting area 21a.

Next, as shown in FIG. 20, the input connecting areas 52s of the first circuit boards 5s incorporating the source drivers 51s are, after positional adjustment, attached to the corresponding first areas 22a of the connecting area 21a (i.e., to the sheet-shaped conductive material 4 attached to the surface thereof). To be specific, the electrode terminals provided on the input connecting areas 52s of the first circuit boards 5s incorporating the source drivers 51s are subjected to positional adjustment so as to be opposed to the corresponding electrode terminals provided on the corresponding first areas 22a of the connecting area 21a of the source-side second circuit board 2a of the first preferred embodiment of the present invention with the sheet-shaped conductive material 4 sandwiched therebetween, and attached to the corresponding electrode terminals.

Then, the first circuit boards 5s incorporating the source drivers 51s are pre-bonded to the source-side second circuit board 2a. For example, heat and pressure are applied to the sheet-shaped conductive material 4 with the use of a pre-bonding machine to the extent that the sheet-shaped conductive material 4 is not cured. Thus, the first circuit boards 5s incorporating the source drivers 51s are pre-bonded to the source-side second circuit board 2a.

Then, the first circuit boards 5s incorporating the source drivers 51s that have been pre-bonded are post-bonded. In the post-bonding, heat and pressure are applied to the sheet-shaped conductive material 4 with the use of a bonding machine. By the post-bonding, the electrode terminals opposed to each other sandwiching the sheet-shaped conductive material 4 (the electrode terminals provided on the input connecting areas 52s of the first circuit boards 5s incorporating the source drivers 51s and the electrode terminals provided on the first areas 22a of the connecting area 21a of the source-side second circuit board 2a) are electrically connected. Further, the sheet-shaped conductive material 4 is cured, which achieves strength in physical connection between the input connecting areas 52s of the first circuit boards 5s incorporating the source drivers 51s and the first areas 22a of the connecting area 21a of the source-side second circuit board 2a.

The connecting structure between the circuit boards 5s incorporating the source drivers 51s and the first areas 22a of the connecting area 21a of the source-side second circuit board 2a is same as the connecting structure between the first area 12 of the connecting area 11 of the circuit board 1 and the connecting area 62 of the another circuit board 6 (see the cross-sectional view of the connecting structure shown in FIG. 16).

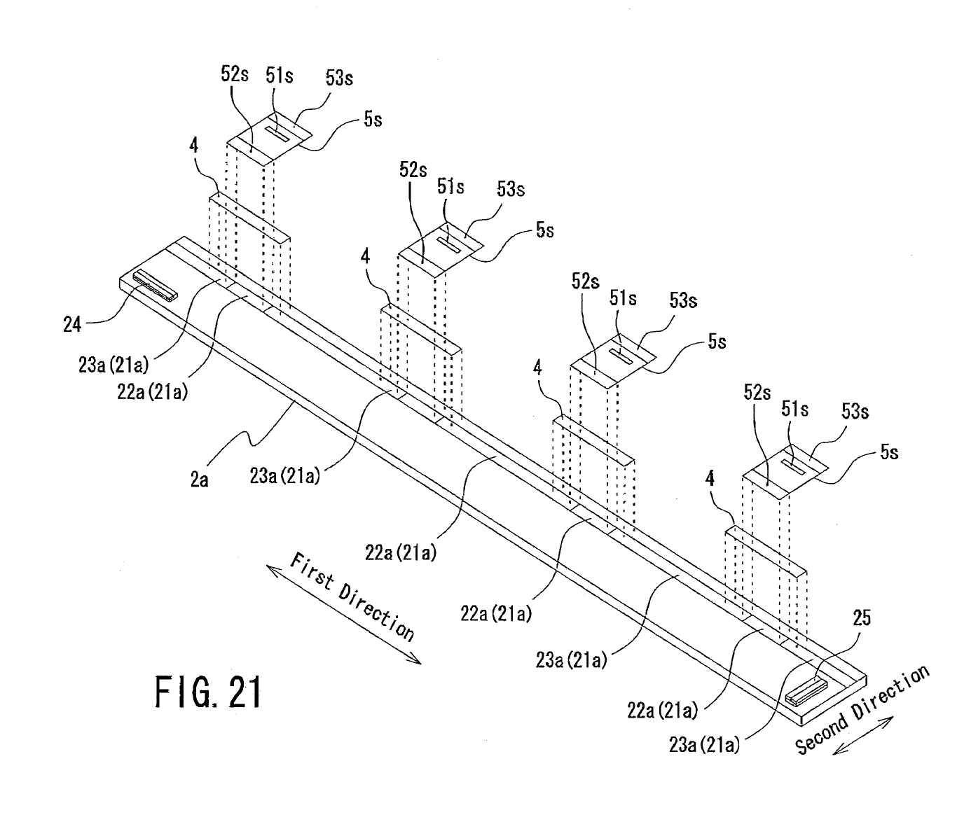

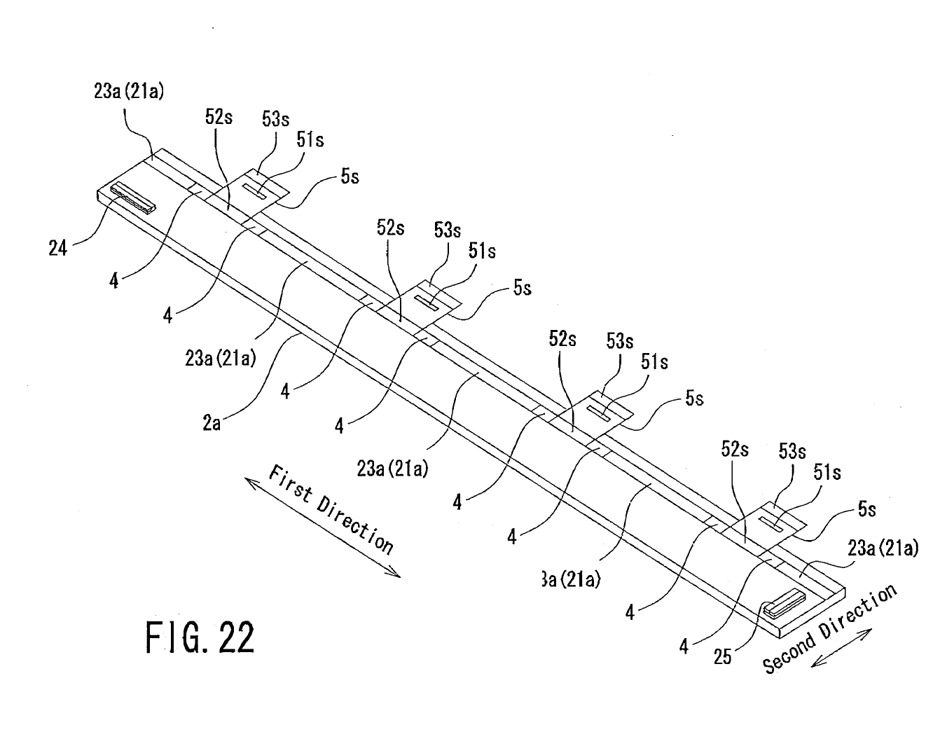

Another connecting structure such that the circuit boards 5s incorporating the source drivers 51s and the source-side second circuit board 2a are connected with the use of a plurality of sheet-shaped conductive materials 4 is also preferable. FIG. 21 is an exploded perspective view schematically showing a connecting method and a connecting structure between the first circuit boards 5s incorporating the source drivers 51s and the source-side second circuit board 2a of the first preferred embodiment of the present invention with the use of the plurality of sheet-shaped conductive materials 4, where the source-side second circuit board 2a and the first circuit boards 5s are yet to be connected. FIG. 22 is an exploded perspective view schematically showing the connecting method and the connecting structure between the first circuit boards 5s incorporating the source drivers 51s and the source-side second circuit board 2a of the first preferred embodiment of the present invention with the use of the plurality of sheet-shaped conductive materials 4, where the source-side second circuit board 2a and the first circuit boards 5s are connected.

As shown in FIGS. 21 and 22, in the connecting method and the connecting structure, the sheet-shaped conductive materials 4 of the same number as the number of the first circuit boards 5s incorporating the source drivers 51s are used (four in FIGS. 21 and 22). The size in the first direction of each sheet-shaped conductive material 4 is larger than the size in the first direction of each first area 22a. The size in the second direction of each sheet-shaped conductive material 4 is as described above.

First, the sheet-shaped conductive materials 4 are attached to the connecting area 21a of the source-side second circuit board 2a at corresponding given positions thereof. To be specific, each sheet-shaped conductive material 4 is attached such that the center in the first direction of each sheet-shaped conductive material 4 covers the entire surface of the corresponding first area 22a of the connecting area 21a, and such that both ends in the first direction of each sheet-shaped conductive material 4 cover at least portions of the surfaces of the second areas 23a that are on both adjacent sides of the corresponding first area 22a (that are adjacent in the first direction to the corresponding first area 22a). In other words, each sheet-shaped conductive material 4 is attached so as to straddle the entire surface of the corresponding first area 22a of the connecting area 21a and the at least portions of the second areas 23a on both the sides of the corresponding first area 22a.

Then, the separators attached to the sheet-shaped conductive materials 4 are peeled off. Because both the ends in the first direction of each sheet-shaped conductive material 4 are attached to the surfaces of the second areas 23a of the connecting area 21a, the sheet-shaped conductive materials 4 are connected tightly to the surfaces of the connecting area 21a by anchor effects produced by the sheet-shaped conductive materials 4 and the island-shaped structural members provided on the second areas 23a of the connecting area 21a. In addition, for the same reason as the circuit board 1, air bubbles are not produced between the sheet-shaped conductive materials 4 and the surface of the second areas 23a, which causes no decrease in connection strength resulting from existence of air bubbles. Thus, in the process of peeling the separator from the sheet-shaped conductive materials 4, the sheet-shaped conductive materials 4 are prevented from being peeled from the connecting area 21a.

Next, the first circuit boards 5s incorporating the source drivers 51s are, after positional adjustment, attached to the corresponding first areas 22a of the connecting area 21a (i.e., to the sheet-shaped conductive materials 4 attached to the surfaces thereof). The positional adjustment is performed as described above. Then, pre-bonding and post-bonding are performed as described above.

Thus, the number of the sheet-shaped conductive material 4 is not limited specifically. That is, it is preferable that the first circuit boards 5s incorporating the source drivers 51s and the source-side second circuit board 2a of the first preferred embodiment of the present invention are connected with the use of one sheet of sheet-shaped conductive material 4, and it is also preferable that the first circuit boards 5s incorporating the source drivers 51s and the source-side second circuit board 2a of the first preferred embodiment of the present invention are connected with the use of the sheet-shaped conductive materials 4 one by one. It is essential only that the sheet-shaped conductive material 4 should be attached so as to straddle the first areas 22a of the connecting area 21a and the second areas 23a. In other words, it is essential only that portions of the sheet-shaped conductive material 4 should be attached to the surfaces of the second areas 23a.

Next, a description of the source-side second circuit boards 2b of the second preferred embodiment of the present invention is provided.

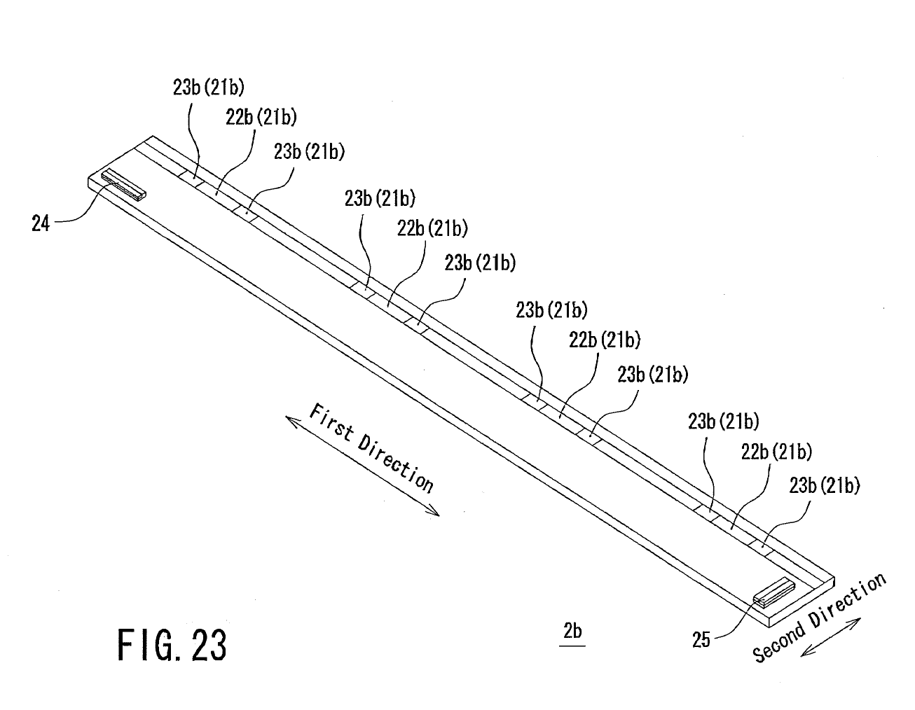

FIG. 23 is an external perspective view schematically showing a configuration of the source-side second circuit board 2b of the second preferred embodiment of the present invention. It is to be noted that a configuration same as that of the source-side second circuit board 2a of the first preferred embodiment of the present invention can be applied to the source-side second circuit board 2b of the second preferred embodiment of the present invention except for the position where second areas 23b are provided. Descriptions of the common configuration are sometimes omitted.

As shown in FIG. 23, a connecting area 21b having a given width (size in the second direction) is provided over the entire length in the first direction of the source-side second circuit board 2b. The connecting area 21b includes a given number of first areas 22b and a given number of second areas 23b. To be specific, the given number of first areas 22b (the same number as the first circuit boards 5s incorporating the source drivers 51s to be connected to: four in FIG. 23) are aligned at given intervals in the first direction. The second areas 23b are disposed on both adjacent sides of the first areas 22b. In other words, one first area 22b is disposed between two second areas 23b.

The first areas 22b have a configuration same as the first area 12 of the connection area 11 of the first circuit board 1. The second areas 23b have a configuration same as the second area 13 of the connection area 11 of the first circuit board 1.

A description of a connecting method and a connecting structure between the source-side second circuit board 2b of the second preferred embodiment of the present invention and the first circuit boards 5s incorporating the source drivers 51s will be provided.

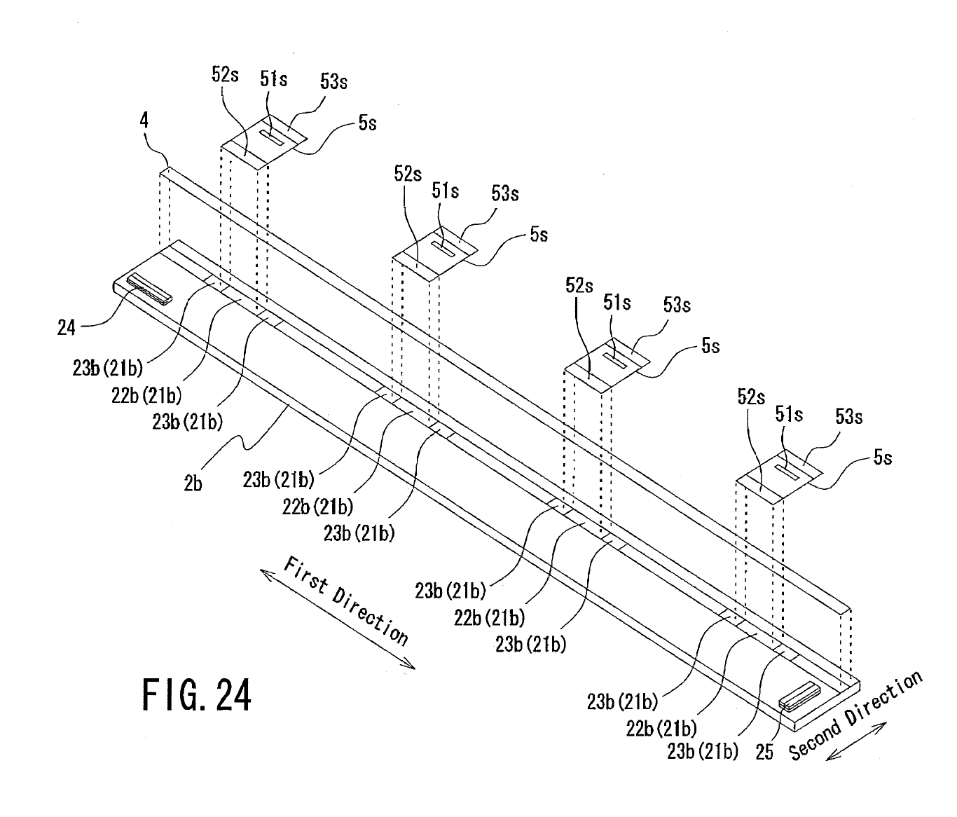

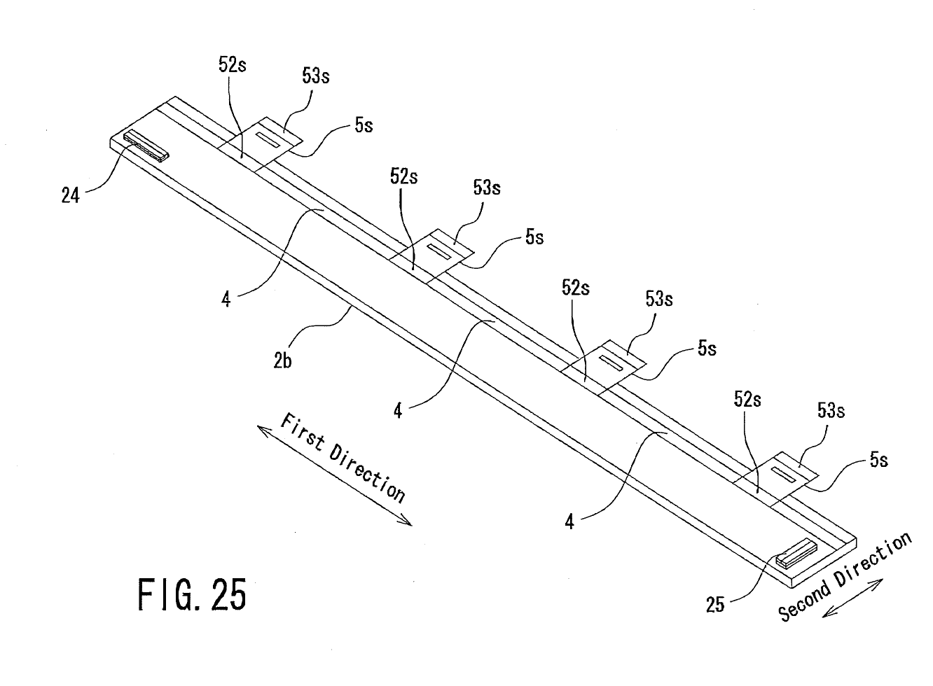

FIG. 24 is an exploded perspective view schematically showing the connecting method and the connecting structure between the source-side second circuit board 2b of the second preferred embodiment of the present invention and the first circuit boards 5s incorporating the source drivers 51s, where the source-side second circuit board 2b and the first circuit boards 5s are yet to be connected. FIG. 25 is an exploded perspective view schematically showing the connecting method and the connecting structure between the source-side second circuit board 2b of the second preferred embodiment of the present invention and the first circuit boards 5s incorporating the source drivers 51s, where the source-side second circuit board 2b and the first circuit boards 5s are connected.

A sheet-shaped conductive material 4 is used to connect the source-side second circuit board 2b and the first circuit boards 5s. A same sheet-shaped conductive material 4 as is used for connecting the source-side second circuit board 2a of the first preferred embodiment of the present invention and the first circuit boards 5s is used for the sheet-shaped conductive material 4. That is, an anisotropic conductive film having the size described above is used.

First, one sheet of the sheet-shaped conductive material 4 is attached over the entire length to the connecting area 21b of the source-side second circuit board 2b as shown in FIG. 24. To be specific, one sheet of the sheet-shaped conductive material 4 is attached thereto with its longer direction parallel to the first direction and with its width direction parallel to the second direction. The second areas 23b of the connecting area 21b of the source-side second circuit board 2b have the configuration same as the second area 13 of the connection area 11 of the first circuit board 1, which prevents air bubbles from being produced between the second areas 23b of the connecting area 21b and the sheet-shaped conductive material 4 for the same reason as the second area 13 of the connection area 11 of the first circuit board 1. Thus, the sheet-shaped conductive material 4 can be brought into intimate contact with the surface of the second areas 23b of the connecting area 21b. In addition, producing an anchor effect, the sheet-shaped conductive material 4 can be connected tightly to the surface of the second areas 23b of the connecting area 21b.

Then, after the sheet-shaped conductive material 4 is attached over the entire length to the connecting area 21b, the separator is peeled off. Thus, the sheet-shaped conductive material 4 is prevented from being peeled from the surface of the connecting area 21b for the same reason as the source-side second circuit board 2a.

Next, as shown in FIG. 25, the input connecting areas 52s of the first circuit boards 5s incorporating the source drivers 51s are, after positional adjustment, attached to the corresponding first areas 22b of the connecting area 21b (i.e., to the sheet-shaped conductive material 4 attached to the surface thereof). Then, the first circuit boards 5s incorporating the source drivers 51s are pre-bonded to the source-side second circuit board 2b. Then, the first circuit boards 5s incorporating the source drivers 51s that have been pre-bonded are post-bonded. The positional adjustment of the input connecting areas 52s of the first circuit boards 5s incorporating the source drivers 51s is performed in the same manner as the source-side second circuit board 2a. In addition, the pre-bonding and post-bonding are performed in the same manner as the source-side second circuit board 2a.

After the post-bonding, electrode terminals opposed to each other sandwiching the sheet-shaped conductive material 4 (the electrode terminals provided on the input connecting areas 52s of the first circuit boards 5s incorporating the source drivers 51s and the electrode terminals provided on the first areas 22b of the connecting area 21b of the source-side second circuit board 2b) are electrically connected. Further, the sheet-shaped conductive material 4 is cured, which achieves strength in physical connection between the input connecting areas 52s of the first circuit boards 5s incorporating the source drivers 51s and the first areas 22b of the connecting area 21b of the source-side second circuit board 2b.

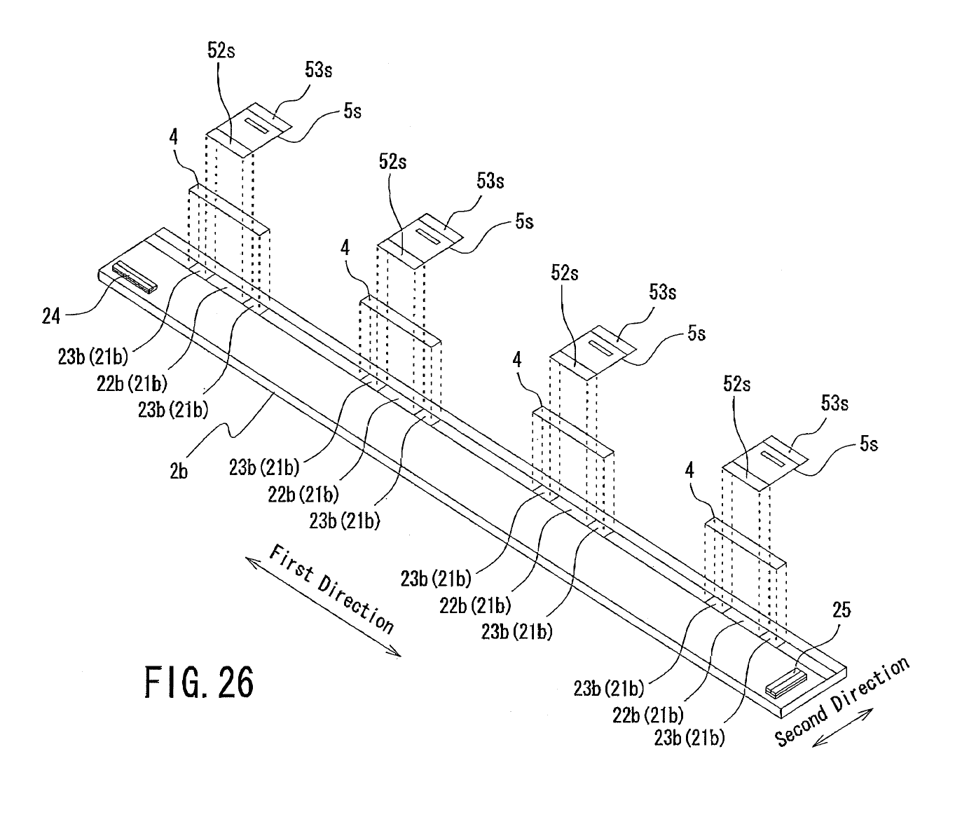

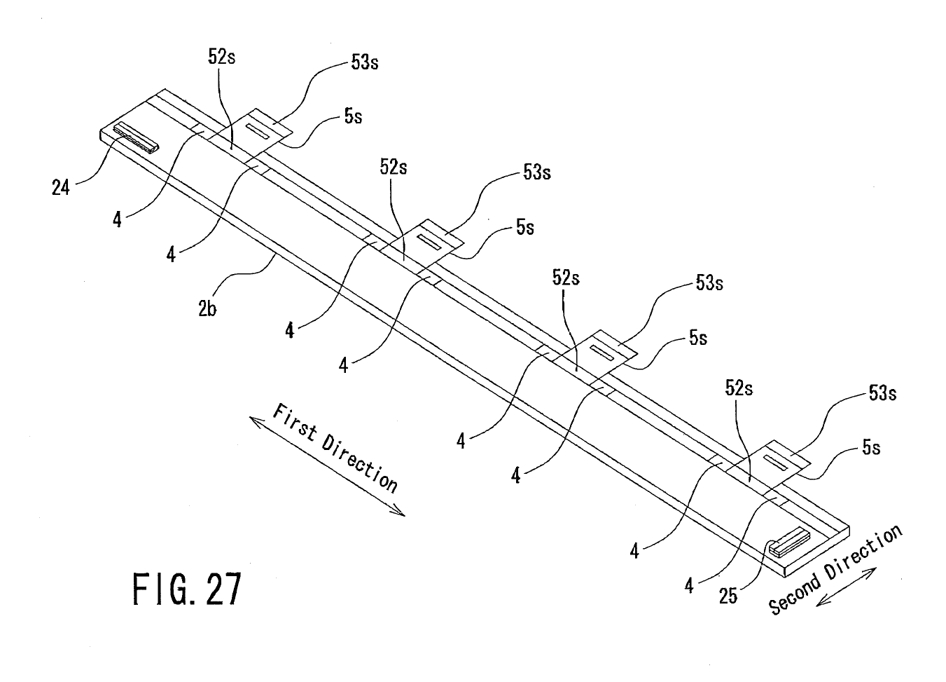

Another connecting structure such that the circuit boards 5s incorporating the source drivers 51s and the source-side second circuit board 2b are connected with the use of a plurality of sheet-shaped conductive materials 4 is also preferable. FIG. 26 is an exploded perspective view schematically showing the connecting method and the connecting structure between the source-side second circuit board 2b and the first circuit boards 5s incorporating the source drivers 51s with the use of the plurality of sheet-shaped conductive materials 4, where the source-side second circuit board 2b and the first circuit boards 5s are yet to be connected. FIG. 27 is an exploded perspective view schematically showing the connecting method and the connecting structure between the source-side second circuit board 2b and the first circuit boards 5s incorporating the source drivers 51s with the use of the plurality of sheet-shaped conductive materials 4, where the source-side second circuit board 2b and the first circuit boards 5s are connected.

As shown in FIGS. 26 and 27, in the connecting method and the connecting structure, the sheet-shaped conductive materials 4 of the same number as the number of the first circuit boards 5s incorporating the source drivers 51s are used (four in FIGS. 21 and 22). The size in the first direction of each sheet-shaped conductive material 4 is larger than the size in the first direction of each first area 22b. It is preferable that the size in the first direction of one sheet-shaped conductive material 4 is same or larger than the sum of the size in the first direction of one first area 22b and the sizes in the first direction of two second areas 23b on both adjacent sides of the one first area 22b. The size in the second direction of each sheet-shaped conductive material 4 is same as that of the sheet-shaped conductive material 4 used for connecting the source-side second circuit board 2a and the source drivers 51s.

First, the sheet-shaped conductive materials 4 are attached to the connecting area 21b of the source-side second circuit board 2b at corresponding positions thereof. To be specific, the sheet-shaped conductive materials 4 are attached thereto with their longer directions parallel to the first direction and with their width directions parallel to the second direction. Each sheet-shaped conductive material 4 is attached such that the center in the first direction of each sheet-shaped conductive material 4 covers the entire surface of the corresponding first area 22b of the connecting area 21b, and such that both ends in the first direction of each sheet-shaped conductive material 4 cover at least portions of the surfaces of the second areas 23b on both ends of the corresponding first area 22b (that are adjacent in the first direction to the corresponding first area 22b). In other words, each sheet-shaped conductive material 4 is attached so as to straddle the corresponding first area 22b of the connecting area 21b and the second areas 23b on both adjacent sides of the first area 22b. If the size in the first direction of one sheet-shaped conductive material 4 is set to be the preferable size described above, the one sheet-shaped conductive material 4 covers the entire surface of the corresponding first area 22b of the connecting area 21b, and the entire surfaces of the second areas 23b on both adjacent sides of the first area 22b.

Then, the separators attached to the sheet-shaped conductive materials 4 are peeled off. Because both the ends in the first direction of each sheet-shaped conductive material 4 are attached to the surfaces of the second areas 23b of the connecting area 21b, the sheet-shaped conductive materials 4 are connected tightly to the surface of the connecting area 21b for the same reason as the circuit board 1. To be specific, the sheet-shaped conductive materials 4 are connected tightly to the surface of the connecting area 21b by anchor effects produced by the sheet-shaped conductive materials 4 and the island-shaped structural members provided on the second areas 23b of the connecting area 21b. In addition, air bubbles are not produced between the sheet-shaped conductive materials 4 and the surface of the second areas 23b, which causes no decrease in connection strength resulting from existence of air bubbles. Thus, in the process of peeling the separators from the sheet-shaped conductive materials 4, the sheet-shaped conductive materials 4 are prevented from being peeled from the connecting area 21b.

Next, as shown in FIG. 27, the first circuit boards 5s incorporating the source drivers 51s are, after positional adjustment, attached to the corresponding first areas 22b of the connecting area 21b (i.e., to the surfaces of the sheet-shaped conductive materials 4 attached to the surfaces thereof). The positional adjustment is performed in the same manner as the source-side second circuit board 2a. Then, the pre-bonding and post-bonding are performed in the same manner as described above.

The same action and effect of connecting structure as those obtained by the connecting structure between the circuit board 1 and the another circuit board 6 can be also obtained.

Next, a description of the source-side second circuit boards 2c of the third preferred embodiment of the present invention is provided.

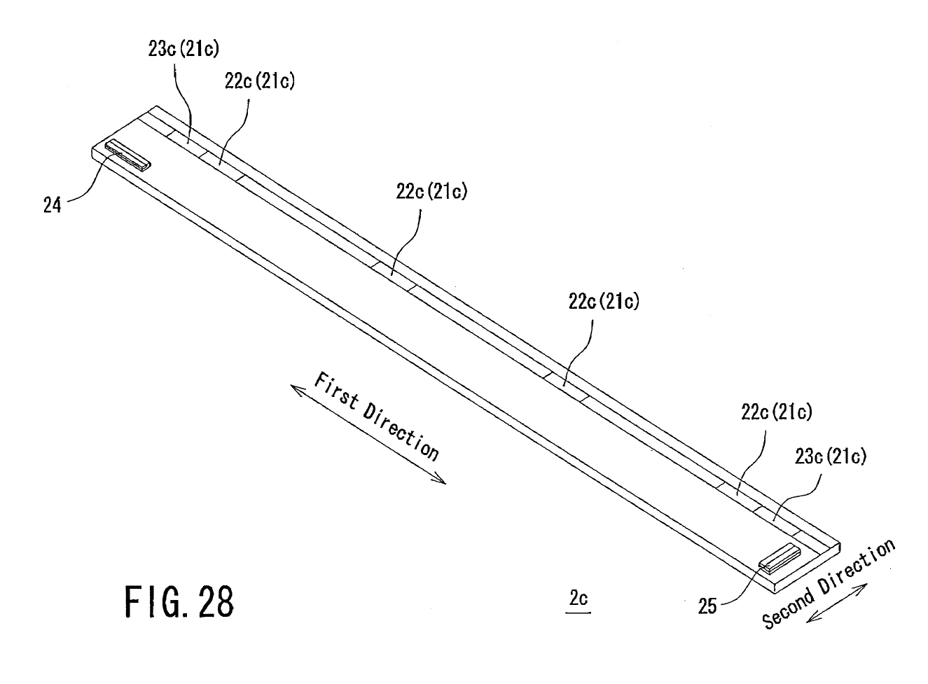

FIG. 28 is an external perspective view schematically showing a configuration of the source-side second circuit board 2c of the third preferred embodiment of the present invention. It is to be noted that a configuration same as that of the source-side second circuit board 2a of the first preferred embodiment of the present invention can be applied to the source-side second circuit board 2c of the third preferred embodiment of the present invention except for the position where second areas 23c are provided. Descriptions of the common configuration are sometimes omitted.

As shown in FIG. 28, a connecting area 21c having a given width (size in the second direction) is provided over the entire length in the first direction of the source-side second circuit board 2c. The connecting area 21c includes a given number of first areas 22c and two second areas 23c. To be specific, the given number of first areas 22c (the same number as the first circuit boards 5s, incorporating the source drivers 51s to be connected to: four in FIG. 28) are aligned at given intervals in the first direction. The two second areas 23c are disposed in the first direction outside of the given number of first areas 22c. In other words, in the configuration where the four first areas 22c are provided, the second area 23c, the first area 22c, the first area 22c, the first area 22c, the first area 22c and the second area 23c are aligned in this order in the first direction from one end to the other end in the connecting area 21c. Thus, the given number of first areas 22c are aligned in the first direction between the two second areas 23c in the connecting area 21c.

The first areas 22c of the connecting area 21c have a configuration same as the first area 12 of the connection area 11 of the first circuit board 1. The second areas 23c of the connecting area 21c have a configuration same as the second area 13 of the connection area 11 of the first circuit board 1. Descriptions thereof are omitted.

A description of a connecting method and a connecting structure between the source-side second circuit board 2c of the third preferred embodiment of the present invention and the first circuit boards 5s incorporating the source drivers 51s will be provided.

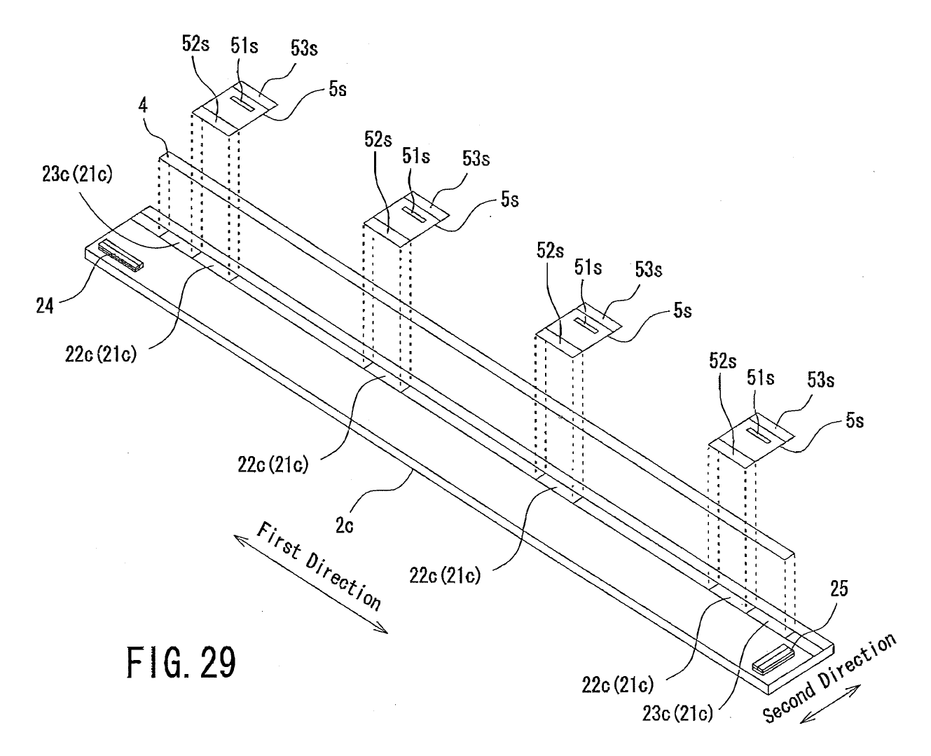

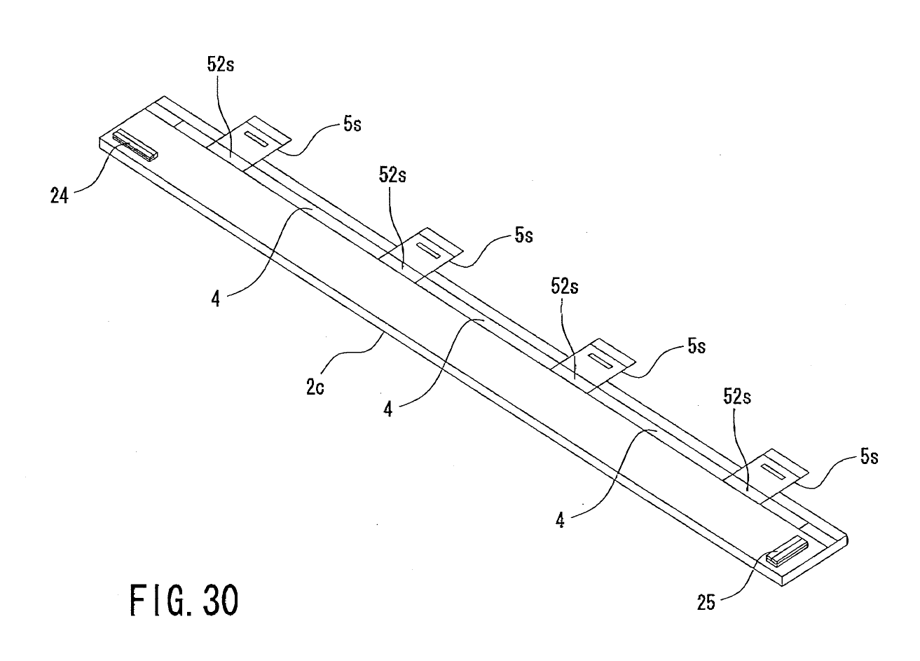

FIG. 29 is an exploded perspective view schematically showing the connecting method and the connecting structure between the source-side second circuit board 2c of the third preferred embodiment of the present invention and the first circuit boards 5s incorporating the source drivers 51s, where the source-side second circuit board 2c and the first circuit boards 5s are yet to be connected. FIG. 30 is an exploded perspective view schematically showing the connecting method and the connecting structure between the source-side second circuit board 2c of the third preferred embodiment of the present invention and the first circuit boards 5s incorporating the source drivers 51s, where the source-side second circuit board 2c and the first circuit boards 5s are connected.

A sheet-shaped conductive material 4 is used to connect the source-side second circuit board 2c and the first circuit boards 5s. A same sheet-shaped conductive material 4 as is used for connecting the source-side second circuit board 2a of the first preferred embodiment of the present invention and the first circuit boards 5s is used for the sheet-shaped conductive material 4.

First, one sheet of the sheet-shaped conductive material 4 is attached over the entire length to the connecting area 21c of the source-side second circuit board 2c as shown in FIG. 29. Thus, both end portions in the first direction of the sheet-shaped conductive material 4 are attached on the second areas 23c of the connecting area 21c. In addition, given portions in the middle in the first direction of the sheet-shaped conductive material 4 are attached to the surfaces of the first areas 22c of the connecting area 21c. In this configuration, portions of the sheet-shaped conductive material 4 are attached to the second areas 23c of the connecting area 21c, which prevents air bubbles from being produced between the second areas 23c of the connecting area 21c and the sheet-shaped conductive material 4 for the same reason as the first circuit board 1. Thus, the sheet-shaped conductive material 4 can be connected tightly to the surfaces of the second areas 23c of the connecting area 21c.

Then, after the sheet-shaped conductive material 4 is attached over the entire length to the connecting area 21c, the separator is peeled off. Thus, the sheet-shaped conductive material 4 is prevented from being peeled from the surface of the connecting area 21c for the same reason as the circuit board 1.

Next, as shown in FIG. 30, the input connecting areas 52s of the first circuit boards 5s incorporating the source drivers 51s are, after positional adjustment, attached to the corresponding first areas 22c of the connecting area 21c (i.e., to the surface of the sheet-shaped conductive material 4 attached to the surface thereof). Then, the first circuit boards 5s incorporating the source drivers 51s are pre-bonded to the source-side second circuit board 2c, and then are post-bonded. The positional adjustment of the input connecting areas 52s of the first circuit boards 5s incorporating the source drivers 51s is performed in the same manner as the source-side second circuit board 2a. In addition, the pre-bonding and post-bonding are performed in the same manner as the source-side second circuit board 2a.

After the post-bonding, electrode terminals opposed to each other sandwiching the sheet-shaped conductive material 4 (the electrode terminals provided on the input connecting areas 52s of the first circuit boards 5s incorporating the source drivers 51s and the electrode terminals provided on the first areas 22c of the connecting area 21c of the source-side second circuit board 2c) are electrically connected. Further, the sheet-shaped conductive material 4 is cured, which achieves strength in physical connection between the input connecting areas 52s of the first circuit boards 5s incorporating the source drivers 51s and the first areas 22c of the connecting area 21c of the source-side second circuit board 2c.

The configuration of the source-side second circuit board 2a, 2b or 2c can be applied also to the configuration of the gate-side second circuit board 82. The connecting method and the connecting structure between the source-side second circuit board 2a, 2b or 2c and the first circuit boards 5s incorporating the source drivers 51s can be applied also to a connecting method and a connecting structure between the gate-side second circuit board 82 and the first circuit boards 5g incorporating the gate drivers 51g. Descriptions thereof are omitted.

In addition, the configuration of the connecting area 11 of the circuit board 1 can be applied also to the configuration of the connecting areas of the TFT array substrate of the display panel 81. The connecting method and the connecting structure between the circuit board 1 and the another circuit board 6 can be applied also to a connecting method and a connecting structure between the TFT array substrate of the display panel 81 and the source-side second circuit boards 5s incorporating the source drivers 51s, and a connecting method and a connecting structure between the TFT array substrate of the display panel 81 and the first circuit boards 5g incorporating the gate drivers 51g.

Next, a description of assembly of the display panel assembly 8 of the preferred embodiment of the present invention will be provided.

The first circuit boards 5s incorporating the source drivers 51s are connected to the corresponding first areas of the connecting areas of the TFT array substrate of the display panel 81. To be specific, the output connecting areas 53s of the first circuit boards 5s incorporating the source drivers 51s are connected to the first areas of the connecting areas on the longer side of the TFT array substrate of the display panel 81. In a similar manner, the output connecting areas of the first circuit boards 5g incorporating the gate drivers 51g are connected to the first areas of the connecting areas 11 on the shorter side of the display panel 81.

Then, the input connecting areas 52s of the first circuit boards 5s incorporating the source drivers 51s are connected to the corresponding first areas 22a, 22b or 22c of the connecting areas 21a, 21b or 21c of the source-side second circuit boards 2a, 2b or 2c. In a similar manner, the output connecting areas of the first circuit boards 5g incorporating the gate drivers 51g are connected to the gate-side second circuit boards 82. In addition, the output connectors 25 of the source-side second circuit boards 2a, 2b or 2c are connected to the connectors of the gate-side second circuit boards 82 with the use of flexible circuit boards 83.

The flow of signals in the display panel assembly 8 is described with reference to FIG. 17. The control signals generated outside are sent to the source-side second circuit boards 2a, 2b or 2c via flexible circuit boards 84, and then sent to the first circuit boards 5s incorporating the source drivers 51s that are connected to the corresponding first areas 22a, 22b or 22c of the connecting areas 21a, 21b or 21c. In addition, the control signals are sent to the gate-side second circuit boards 82 via the output connectors 25 and the flexible circuit boards 83 that are connected to the output connectors 25. The control signals sent to the gate-side second circuit boards 82 are sent to the first circuit boards 5g incorporating the gate drivers 51g that are connected to the gate-side second circuit boards 82.

The source drivers 51s generate given signals based on the control signals. In a similar manner, the gate drivers 51g generate given signals based on the control signals. The given signals generated by the source drivers 51s are sent to the source lines via the output connecting areas 53s and the electrode terminals on the first areas of the connecting areas of the TFT array substrate of the display panel 81. In a similar manner, the given signals generated by the gate drivers 51g are sent to the gate lines via the output connecting areas and the electrode terminals on the first areas of the connecting areas of the TFT array substrate of the display panel 81.

Described above is the display panel assembly 8 having the configuration that the source-side second circuit boards 2a, 2b or 2c are connected to the gate-side second circuit boards 82 with the use of the flexible circuit boards 83; however, the configuration is not limited thereto. For example, the display panel assembly 8 may have a configuration that the control signals are sent to the gate-side second circuit boards 82 via the first circuit boards 5s incorporating the source drivers 51s connected to the source-side second circuit boards 2a, 2b or 2c, and via the lines provided on the TFT array substrate of the display panel 81.

In addition, the display panel assembly 8 may have a configuration of having no gate-side second circuit boards 82. In this configuration, the control signals are sent to the first circuit boards 5g incorporating the gate drivers 51g via the first circuit boards 5s incorporating the source drivers 51s connected to the source-side second circuit boards 2a, 2b or 2c, and via the lines provided on the TFT array substrate of the display panel 81.

The foregoing description of the preferred embodiments of the present invention has been presented for purposes of illustration and description with reference to the drawings. However, it is not intended to limit the present invention to the preferred embodiments, and modifications and variations are possible as long as they do not deviate from the principles of the present invention.

1. A circuit board comprising:
a first area comprising a predetermined number of electrode terminals; and
a second area comprising a predetermined number of structural members having an island shape,
wherein the first area and the second area are aligned in a first direction,
wherein at least some of the island-shaped structural members have a size in a direction substantially perpendicular to the first direction that is smaller than a size in the direction substantially perpendicular to the first direction of the second area.

2. The circuit board according to claim 1, wherein the island-shaped structural members, which have the size in the direction substantially perpendicular to the first direction that is smaller than the size in the direction substantially perpendicular to the first direction of the second area, are aligned in the direction substantially perpendicular to the first direction in the second area.

3. The circuit board according to claim 1, wherein the island-shaped structural members, which have the size in the direction substantially perpendicular to the first direction that is smaller than the size in the direction substantially perpendicular to the first direction of the second area, are aligned any one of:
in a zigzag arrangement in the direction substantially perpendicular to the first direction in the second area.

4. The circuit board according to claim 1, wherein each of the island-shaped structural members, which have the size in the direction substantially perpendicular to the first direction that is smaller than the size in the direction substantially perpendicular to the first direction of the second area, comprises:
main bodies, each of which has a predetermined overall size; and
connecting portions, each of which has a width that is smaller than the overall size of each main body, the connecting portions connecting the main bodies.

5. The circuit board according to claim 1, wherein the island-shaped structural members are made from a conductor film same as a conductor film from which the electrode terminals are made.

6. The circuit board according to claim 1, wherein the island-shaped structural members are made from any one of photoresist material, and an ink.

7. The circuit board according to claim 1, wherein the first area comprises a plurality of first areas that are aligned in the first direction, and the second area comprises a plurality of second areas,
wherein the second areas are disposed between the first areas.

8. The circuit board according to claim 1, wherein the first area comprises a plurality of first areas that are aligned in the first direction, and the second area comprises a plurality of second areas,
wherein the second areas are disposed in the first direction adjacent to the first areas.

9. The circuit board according to claim 8, wherein the second areas are disposed in the first direction on both adjacent sides of the first areas.

10. The circuit board according to claim 1, wherein the first area comprises a plurality of first areas that are aligned in the first direction, and the second area comprises a plurality of second areas,
wherein the second areas are disposed in the first direction outside of the first areas disposed at the ends of the circuit board.

11. The circuit board according to claim 1, wherein the first area comprises a plurality of first areas that are aligned in the first direction, and the second area comprises a plurality of second areas,
wherein at least two of the second areas are disposed at predetermined intervals in the first direction,
wherein the first areas are disposed in the first direction between the second areas.

12. A connecting structure of the circuit board according to claim 1 that is connected to another circuit board comprising a predetermined number of electrode terminals with the use of a conductive material,
wherein the predetermined number of electrode terminals on the first area of the circuit board according to claim 1 are opposed, sandwiching the conductive material, to the corresponding electrode terminals on the another circuit board,
wherein the conductive material covers at least a portion of the second area of the circuit board according to claim 1, whereby the conductive material covers entire surfaces of the island-shaped structural members, which have the size in the direction substantially perpendicular to the first direction that is smaller than the size in the direction substantially perpendicular to the first direction of the second area.

13. The connecting structure according to claim 12, wherein a size in the direction substantially perpendicular to the first direction of the conductive material is larger than the size in the direction substantially perpendicular to the first direction of the second area,
wherein the second area comprises a portion that is covered over the entire length in the direction substantially perpendicular to the first direction with the conductive material.

14. The connecting structure according to claim 12, wherein the
conductive material comprises an anisotropic conductive film.

15. The connecting structure according to claim 14, wherein, the anisotropic conductive film has the shape of a long strip, and has a width that is larger than the size in the direction substantially perpendicular to the first direction of the second area,
wherein the anisotropic conductive film is attached to the first area and the second area with its longer direction in the first direction so as to straddle an entire surface of the first area and at least a portion of the second area.

16. A display panel assembly comprising:
a display panel;
a first circuit board comprising a predetermined number of electrode terminals, which is connected to the display panel;
a second circuit board connected to the first circuit board, the second circuit board comprising:
a first area comprising a predetermined number of electrode terminals; and
a second area comprising a predetermined number of structural members having an island shape,
wherein the first area and the second area are aligned in a first direction,
wherein at least some of the island-shaped structural members have a size in a direction substantially perpendicular to the first direction that is smaller than a size in the direction substantially perpendicular to the first direction of the second area,
wherein a conductive material is attached to the first area and the second area so as to straddle an entire surface of the first area and at least a portion of the second area,
wherein the electrode terminals on the first circuit board are opposed, sandwiching the conductive material, to the predetermined number of corresponding electrode terminals on the first area of the second circuit board,
wherein the conductive material covers entire surfaces of the island-shaped structural members, which have the size in the direction substantially perpendicular to the first direction that is smaller than the size in the direction substantially perpendicular to the first direction of the second area.

17. The display panel assembly according to claim 16, wherein the island-shaped structural members, which have the size in the direction substantially perpendicular to the first direction that is smaller than the size in the direction substantially perpendicular to the first direction of the second area, are aligned in the direction substantially perpendicular to the first direction in the second area of the second circuit board.

18. The circuit board display panel according to claim 16, wherein the island-shaped structural members, which have the size in the direction substantially perpendicular to the first direction that is smaller than the width of the long strip-shaped conductive material size in the direction substantially perpendicular to the first direction of the second area, are aligned in a direction inclined predetermined angles toward the first direction in the second area any one of:
in a zigzag arrangement in the direction substantially perpendicular to the first direction in the second area of the second circuit board;
in a direction inclined predetermined angles toward the first direction in the second area of the second circuit board; and
in a random fashion in the second area of the second circuit board.

19. The display panel assembly according to claim 16, wherein each of the island-shaped structural members, which have the size in the direction substantially perpendicular to the first direction that is smaller than the size in the direction substantially perpendicular to the first direction of the second area, comprises:
main bodies, each of which has a predetermined overall size; and
connection portions, each of which has a width that is smaller than the overall size of each main body, the connecting portions connecting the main bodies.

20-50. (canceled)
